(19) United States
(12) Patent Application Publication
(10) Pub. No.: US 2016/0078953 A1
(43) Pub. Date: Mar. 17, 2016

(54) SEMICONDUCTOR MEMORY DEVICE

(71) Applicant: KABUSHIKI KAISHA TOSHIBA, Tokyo (JP)

(72) Inventors: Sanad BUSHNAQ, Yokohama (JP); Masanobu SHIRAKAWA, Chigasaki (JP)

(21) Appl. No.: 14/633,037

(22) Filed: Feb. 26, 2015

(30) Foreign Application Priority Data
Sep. 12, 2014 (JP) 2014-187076

(51) Int. Cl. G11C 16/26; G11C 16/24; G11C 16/04

(52) U.S. Cl. CPC G11C 16/26; G11C 16/0483; G11C 16/24

(57) ABSTRACT

A semiconductor memory device includes a first memory cell and a second memory cell having a parasitic capacitance smaller than a parasitic capacitance of the first memory cell, a first bit line that is electrically connected to the first memory cell, a second bit line that is electrically connected to the second memory cell, a first sense module that is electrically connected to the first bit line through a first transistor, and a second sense module that is electrically connected to the second bit line through a second transistor. During sensing of the first and second bit lines, the first and second transistors are turned on for first and second periods of time, respectively, to electrically connect the first and second sense modules to the corresponding first and second bit lines. The first period of time is longer than the second period of time.

### CROSS-REFERENCE TO RELATED APPLICATION

This application is based upon and claims the benefit of priority from Japanese Patent Application No. 2014-187076, filed Sep. 12, 2014, the entire contents of which are incorporated herein by reference.

### FIELD

Embodiments described herein relate generally to a semiconductor memory device.

### BACKGROUND

There is a NAND flash memory in which memory cells are arranged in a three-dimensional manner.

### DESCRIPTION OF THE DRAWINGS

FIG. 1 is a diagram illustrating a configuration of a memory system including a semiconductor memory device.

FIG. 2 is a block diagram of a NAND flash memory.

FIG. 3 is a diagram illustrating a configuration of a memory cell array.

FIG. 4 is a cross-sectional view illustrating a relationship between a source line contact and a semiconductor pillar provided in the NAND flash memory.

FIG. 5 is a plan view illustrating a relationship between the source line contact and the semiconductor pillar provided in the NAND flash memory.

FIG. 6 is a circuit diagram illustrating a configuration of a sense module.

FIG. 7 is a timing chart of various control signals of the sense module according to a first embodiment.

FIG. 8 is a plan view illustrating a relationship between the source line contact and the semiconductor pillar provided in the NAND flash memory.

FIG. 9 is a timing chart of various control signals of the sense module according to a first modification example.

FIG. 10 is a timing chart of various control signals of the sense module according to a second embodiment.

FIG. 11 is a timing chart of various control signals of the sense module according to a second modification example.

FIG. 12 is a circuit diagram illustrating a connection relationship between a bit line and the sense module.

FIG. 13 is a circuit diagram illustrating a configuration of the sense module.

FIG. 14 is a timing chart of various control signals of the sense module according to a third embodiment.

FIG. 15 is a timing chart of various control signals of the sense module according to a third modification example.

FIG. 16 is a timing chart of various control signals of the sense module according to a fourth embodiment.

FIG. 17 is a timing chart of various control signals of the sense module according to a fourth modification example.

FIG. 18 is a timing chart of various control signals of the sense module according to a fifth embodiment.

FIG. 19 is a timing chart of various control signals of the sense module according to a fifth modification example.

FIG. 20 is a circuit diagram illustrating a configuration of a sense module.

FIG. 21 is a timing chart of various control signals of the sense module according to a sixth embodiment.

FIG. 22 is a timing chart of various control signals of the sense module according to a sixth modification example.

FIG. 23 is a timing chart of various control signals of the sense module according to a seventh embodiment.

FIG. 24 is a timing chart of various control signals of the sense module according to a seventh modification example.

FIG. 25 is a timing chart of various control signals of the sense module according to an eighth embodiment.

FIG. 26 is a timing chart of various control signals of the sense module according to an eighth modification example.

FIG. 27 is a circuit diagram illustrating part of a block.

FIG. 28 is a plan view illustrating part of the block.

FIG. 29 is a perspective view of the block.

FIG. 30 is a cross-sectional view taken along the line A-A of FIG. 28.

FIG. 31 is a cross-sectional view taken along the line B-B of FIG. 28.

FIG. 32 is a cross-sectional view taken along the line C-C of FIG. 28.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to limit the scope of the invention. As used herein, the singular forms “a,” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

An exemplary embodiment provides a semiconductor memory device capable of improving operation reliability.

In general, according to one embodiment, a semiconductor memory device includes a memory cell array including a first memory cell and a second memory cell having a parasitic capacitance smaller than a parasitic capacitance of the first memory cell, a first bit line that is electrically connected to the first memory cell, a second bit line that is electrically connected to the second memory cell, a first sense module that is electrically connected to the first bit line through a first transistor, and a second sense module that is electrically connected to the second bit line through a second transistor. During sensing data stored in the first memory cell, the first transistor is turned on for a first period of time to electrically connect the first sense module to the first bit line. During sensing data stored in the second memory cell, the second transistor is turned on for a second period of time that is shorter than the first period of time, to electrically connect the second sense module to the second bit line.

Hereinafter, exemplary embodiments will be described with reference to the drawings. In the description, similar reference numerals are given to similar portions throughout all the drawings.

### First Embodiment

A description will be made of a semiconductor memory device according to a first embodiment. Hereinafter, a three-dimensional stacked NAND flash memory in which memory cell transistors are stacked over a semiconductor substrate will be described as an example of the semiconductor memory device.

Configuration of Memory System

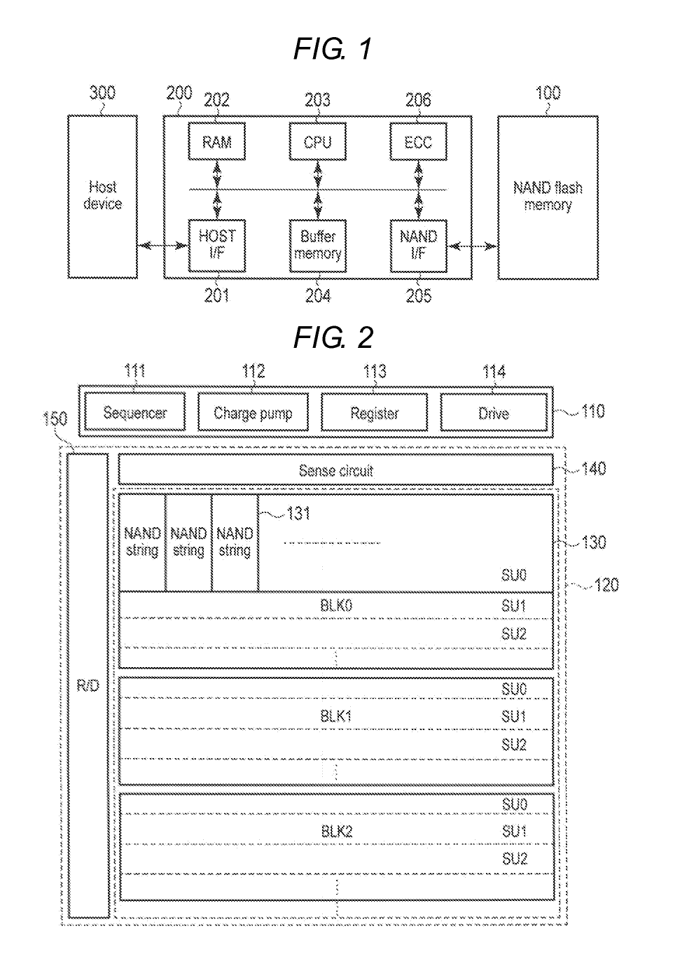

First, with reference to FIG. 1, a description will be made of a configuration of a memory system including the semiconductor memory device according to the present embodiment.

As illustrated in FIG. 1, a memory system 1 includes a NAND flash memory 100 and a memory controller 200. The memory controller 200 and the NAND flash memory 100 may form a single semiconductor device, for example, through a combination thereof, and, as an example thereof, there may be a memory card such as an SD™ card, or a solid state drive (SSD). The memory system 1 may further include a host device 300.

The NAND flash memory 100 includes a plurality of memory cell transistors, and stores data in a nonvolatile manner. Details of a configuration of the NAND flash memory 100 will be described later.

In response to commands from the host device 300, the memory controller 200 gives commands for reading, writing, erasing, or the like to the NAND flash memory 100.

The memory controller 200 includes a host interface circuit 201, an internal memory (RAM) 202, a processor (CPU) 203, a buffer memory 204, a NAND interface circuit 205, an ECC circuit 206.

The host interface circuit 201 is connected to the host device 300 via a controller bus, and relays communication between the memory controller 200 and the host device 300. The host interface circuit 201 transmits a command and data which are received from the host device 300, to the CPU 203 and the buffer memory 204, respectively. The host interface circuit 201 transmits the data in the buffer memory 204 to the host device 300 in response to a command from the CPU 203.

The NAND interface circuit 205 is connected to the NAND flash memory 100 via a NAND bus. The NAND interface circuit 205 relays communication between the NAND flash memory 100 and the memory controller 200. The NAND interface circuit 205 transmits a command received from the CPU 203, to the NAND flash memory 100. The NAND interface circuit 205 transmits written data in the buffer memory 204 to the NAND flash memory 100 during writing data. The NAND interface circuit 205 transmits data read from the NAND flash memory 100 to the buffer memory 204 during reading data.

The CPU 203 controls the entire operation of the memory controller 200. For example, if a writing command is received from the host device 300, the CPU 203 issues a writing command based on the NAND interface circuit 205. This is also the same for reading and erasing. The CPU 203 performs various processes for managing the NAND flash memory 100, such as wear leveling. The CPU 203 performs various calculations. For example, a data encryption process or randomizing process is performed. In addition, as described above, also in a case where the host device 300 is included in the memory system 1, the CPU 203 controls an operation of the entire memory system 1.

The ECC circuit 206 performs data error checking and correcting (ECC) processes. In other words, the ECC circuit 206 generates parity based on data to be written during writing data. The ECC circuit 206 generates syndrome from the parity during reading data, so as to detect an error, and corrects the error. The CPU 203 may have the function of the ECC circuit 206.

The internal memory 202 is a semiconductor memory such as a DRAM, and is used as a work area of the CPU 203. The internal memory 202 holds, for example, firmware or various management tables for managing the NAND flash memory 100.

Configuration of Semiconductor Memory Device

Next, with reference to FIG. 2, a configuration of the semiconductor memory device 100 will be described.

As illustrated in FIG. 2, the NAND flash memory 100 roughly includes peripheral circuits 110 and a core section 120.

The core section 120 includes a memory cell array 130, a sense circuit 140, and a row decoder 150.

The memory cell array 130 includes a plurality of nonvolatile memory cell transistors, and each of the plurality of nonvolatile memory cell transistors is associated with a word line and a bit line. The memory cell array 130 includes a plurality of (in an example of FIG. 2, three) blocks BLK (BLK0, BLK1, BLK2, . . . ) which are sets of the plurality of nonvolatile memory cell transistors. The block BLK is the data erasing unit, and data items in the same block BLK are collectively erased. Each block BLK includes a plurality of string units SU (SU0, SU1, SU2, . . . ) which are sets of NAND strings 131 in which the memory cell transistors are connected in series to each other. Of course, the number of blocks in the memory cell array 130 or the number of string units in a single block BLK is arbitrary.

The row decoder 150 decodes a block address or a page address, so as to selection any one of word lines of a corresponding block. The row decoder 150 applies appropriate voltages to a selected word line and an unselected word line.

The sense circuit 140 includes a plurality of sense modules 141, and senses data which is read from a memory cell transistor to a bit line during reading data. During writing data, data to be written is transmitted to the memory cell transistor. The data reading and writing from and to the memory cell array 130 are performed in the units of a plurality of memory cell transistors.

The peripheral circuits 110 include a sequencer 111, a charge pump 112, a register 113, and a driver 114.

The sequencer 111 controls an operation of the entire NAND flash memory 100.

The driver 114 supplies voltages required to write, read, and erase data, to the row decoder 150, the sense circuit 140, and a source line driver (not illustrated).

The charge pump 112 steps up a power supply voltage given from an external device, and supplies a necessary voltage to the driver 114.

The register 113 holds various signals. For example, the register 113 holds a status of a data writing or erasing operation, and thus notifies the controller that the operation has been normally completed. The register 113 may hold various tables.

Memory Cell Array

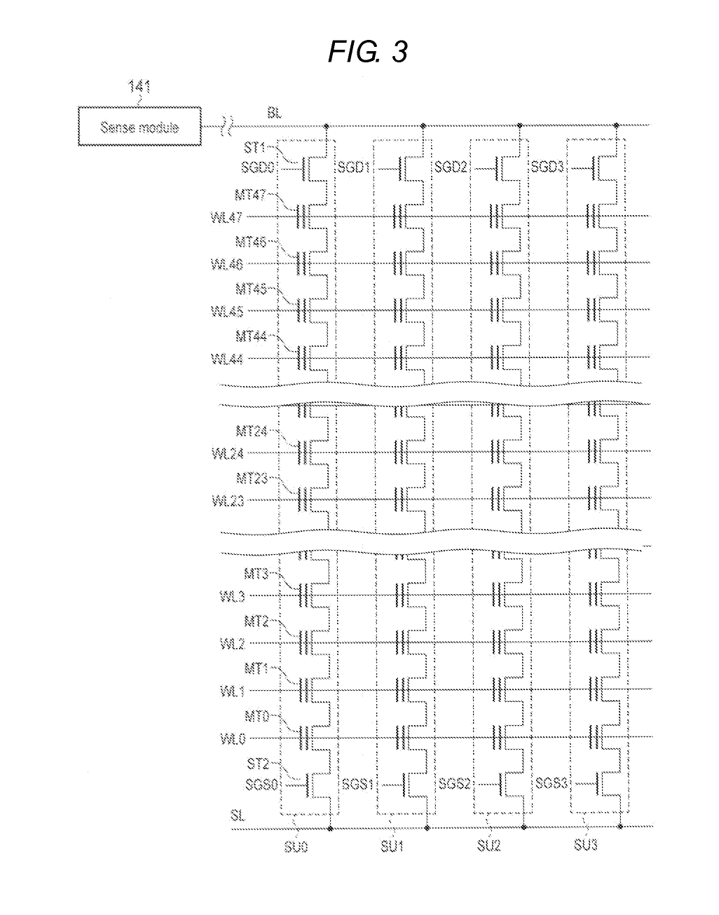

Next, with reference to FIG. 3, a configuration of the memory cell array 130 according to the first embodiment will be described in detail.

Each of the NAND strings 131 includes, for example, forty-eight memory cell transistors MT (MT0 to MT47) and selection transistors ST1 and ST2. Each of the memory cell transistors MT is provided with a stacked gate including a control gate and a charge storage layer, and stores data in a nonvolatile manner. The number of the memory cell transistors MT is not limited to 48, and may be 8, 16, 32, 64, 128, or the like, and the number thereof is not limited. If the memory cell transistors MT0 to MT47 are not distinguished from each other, the memory cell transistors are simply referred to as (a) memory cell transistor(s) MT.

The plurality of memory cell transistors MT are disposed to be connected in series to each other between the selection transistors ST1 and ST2.

Gates of the selection transistors ST1 of the string units SU0 to SU3 are respectively connected to selection gate lines SDG0 to SGD3, and gates of the selection transistors ST2 are respectively connected to selection gate lines SGS0 to SGS3. In contrast, control gates of the memory cell transistors MT0 to MT47 in the same block BLK0 are respectively connected in common to word lines WL0 to WL47. In addition, if the word lines WL0 to WL47 are not distinguished from each other, the word lines are simply referred to as (a) word line(s) WL.

In other words, the word lines WL0 to WL47 are connected in common to the plurality of string units SU0 to SU3 in the same block BLK0, but the selection gate lines SGD and SGS are independent for the respective string units SU0 to SU3 even within the same block BLK0.

In the block BLK0, the column configuration as illustrated in FIG. 3 is provided in a plurality in a vertical direction to the drawing surface. In the first embodiment, the block BLK0 includes, for example, four string units SU (SU0 to SU3). Each string unit SU includes a plurality of NAND strings 131 in the vertical direction of the drawing surface of FIG. 3. Other blocks BLK have the same configuration as that of the block BLK0.

Among the NAND strings 131 disposed in a matrix in the memory cell array 130, the other ends of the selection transistors ST1 of the NAND strings 131 located in the same row are connected in common to any one of bit lines BL (BL0 to BL(L−1), where (L−1) is a natural number of 1 or greater). In other words, the bit line BL connects the NAND strings 131 in common between a plurality of blocks BLK. The other ends of current paths of the selection transistors ST2 are connected in common to a source line SL. The source line SL connects the NAND strings 131 in common, for example, between a plurality of blocks.

As described above, data items of the memory cell transistors MT located in the same block BLK are collectively erased. In contrast, reading and programming of data are collectively performed on a plurality of memory cell transistors MT which are connected in common to any one of the word lines WL in any one of the string units SU of any one of blocks BLK. The above-described collective writing unit is referred to as a “page”.

A configuration of the memory cell array 130 may be as disclosed in, for example, U.S. patent application Ser. No. 12/407,403, filed on Mar. 19, 2009, entitled “three dimensional stacked nonvolatile semiconductor memory”. In addition, a configuration thereof may be as disclosed in U.S. patent application Ser. No. 12/406,524, filed on Mar. 18, 2009, entitled “three dimensional stacked nonvolatile semiconductor memory”, U.S. patent application Ser. No. 12/679,991, filed on Mar. 25, 2010, entitled “non-volatile semiconductor storage device and method of manufacturing the same”, and U.S. patent application Ser. No. 12/532,030, filed on Mar. 23, 2009, entitled “semiconductor memory and method for manufacturing same”. The entire contents of these patent applications are incorporated by reference herein.

Source Line Contact and Substrate Contact

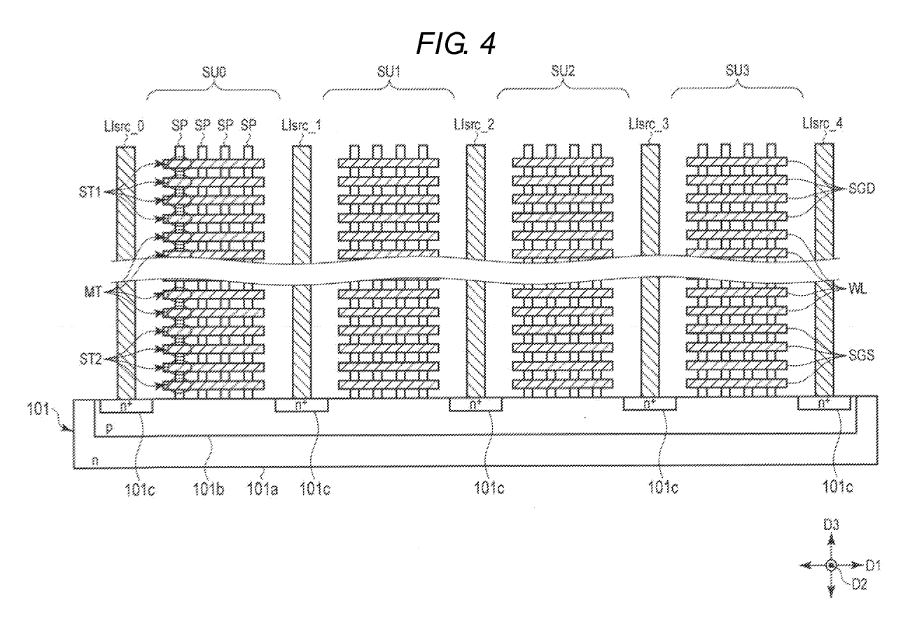

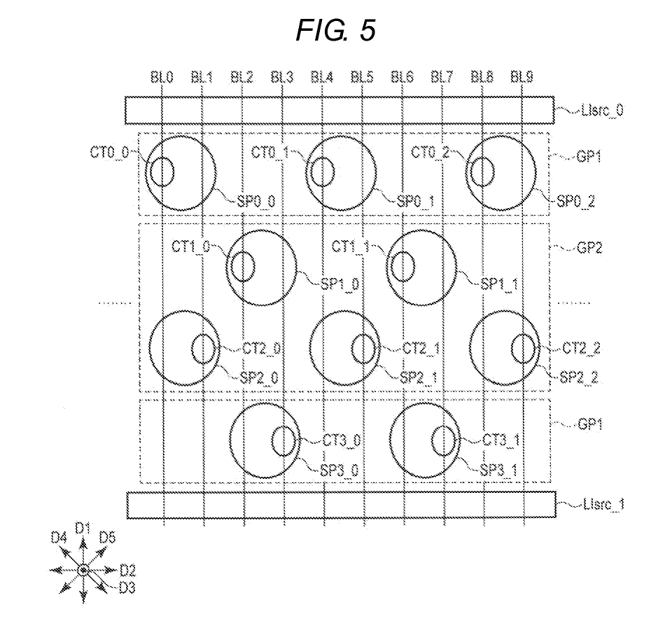

With reference to FIGS. 4 and 5, a description will be made of a source line contact LIsrc and a semiconductor pillar included in the NAND flash memory according to the present embodiment.

As illustrated in FIG. 4, an n type well 101a is provided in a semiconductor substrate 101, and a p type well 101b is provided in a surface region of the n type well 101a. In addition, n type diffusion layers 101c are provided in a surface region of the p type well 101b.

The memory cell array 130 includes a plurality of plate-shaped source line contacts LIsrc. The source line contacts LIsrc are provided on the n type diffusion layers 101c. The source line contact LIsrc electrically connects the semiconductor substrate 101 to the source line (not illustrated) via a contact CT (not illustrated).

For example, a source line contact LIsrc_0 is disposed at a boundary of the block BLK0. A source line contact LIsrc_1 is disposed at a boundary between the block BLK0 and the block BLK1 adjacent thereto. If the source line contact LIsrc_0 and the source line contact LIsrc_1 are not distinguished from each other, the source line contacts are simply referred to as source line contact LI or the like.

In the memory cell array 130, semiconductor pillars SP are provided to extend in the vertical direction (D3 direction) to the semiconductor substrate. The respective transistors MT, ST1 and ST2 are connected in series to each other in the D3 direction with the semiconductor pillar SP as a central axis. In other words, the respective transistors MT, ST1 and ST2 are provided in regions including the semiconductor pillars SP, and word lines WL and the selection gate lines SGD and SGS which are provided in multiple stages.

Next, with reference to FIG. 5, a description will be made of a disposition of the semiconductor pillars SP and a relationship between the bit line BL and the semiconductor pillar SP in a D1-D2 plane perpendicular to the D3 direction.

As illustrated in FIG. 5, a semiconductor pillar SP0 group (SP0_0, SP0_1, . . . ) which is adjacent to the source line contact LIsrc_0 in the D1 direction is provided in the memory cell array 130. A semiconductor pillar SP1 group (SP1_0, SP1_1, . . . ) adjacent to the semiconductor pillar SP0 group in the D4 direction (intersecting the D1 direction and the D2 direction with a predetermined angle therebetween in the D1-D2 plane) or the D5 direction (intersecting the D1 direction, the D2 direction, and the D4 direction in the D1-D2 plane) is provided in the memory cell array 130. In addition, a semiconductor pillar SP2 group (SP2_0, SP2_1, . . . ) which is adjacent to the semiconductor pillar SP1 group in the D4 direction or the D5 direction is provided in the memory cell array 130. Further, a semiconductor pillar SP3 group (SP3_0, SP3_1, . . . ) which is adjacent to the semiconductor pillar SP2 group in the D4 direction or the D5 direction and is adjacent to the source line contact LIsrc_1 in the D1 direction is provided in the memory cell array 130. If the semiconductor pillars SP0 to SP3 are not distinguished from each other, the semiconductor pillars are simply referred to as semiconductor pillars SP or the like.

The bit line BL0 is connected to a contact CT0_0 of the semiconductor pillar SP0_0. The bit line BL1 is connected to a contact CT2_0 of the semiconductor pillar SP2_0. The bit line BL2 is connected to a contact CT1_0 of the semiconductor pillar SP1_0. The bit line BL3 is connected to a contact CT3_0 of the semiconductor pillar SP3_0. In the above-described manner, other bit lines BL are connected to the semiconductor pillars SP via the contacts CT. If the contacts CT0_0 to CT3_0 are not distinguished from each other, the contacts are simply referred to as contacts CT or the like.

In the present embodiment, a plurality of semiconductor pillars SP adjacent to the source line contact LIsrc are classified into a first group GP1, and a plurality of semiconductor pillars SP which are not adjacent to the source line contact LIsrc are classified into a second group GP2.

More specifically, in the present embodiment, the semiconductor pillar SP0 group and the semiconductor pillar SP3 group are defined as a first semiconductor pillar group SPGP1 included in the first group GP1. The semiconductor pillar SP1 group and the semiconductor pillar SP2 group are defined as a second semiconductor pillar group SPGP2 included in the second group GP2.

In the present embodiment, the bit lines BL connected to the first semiconductor pillar group SPGP1 are also referred to as a first group bit line BLGP1 or the like. The bit lines BL connected to the second semiconductor pillar group SPGP2 are also referred to as a second group bit line BLGP2 or the like.

Bit line capacitances (hereinafter, the bit line capacitance is also simply referred to as a capacitance) of the first group bit line BLGP1 and the second group bit line BLGP2 may be different from each other depending on a distance between the plurality of semiconductor pillars SP and a distance between the semiconductor pillar SP and the source line contact LIsrc. In the present embodiment, the sequencer 111 operates the sense circuit 140 in consideration of a difference between a capacitance of the first group bit line BLGP1 and a capacitance of the second group bit line BLGP2. Hereinafter, an operation of the sense circuit 140 will be described in detail.

In addition, hereinafter, for simplification, a description will be made of a case where the capacitance of the first group bit line BLGP1 is larger than the capacitance of the second group bit line BLGP2.

Sense Module

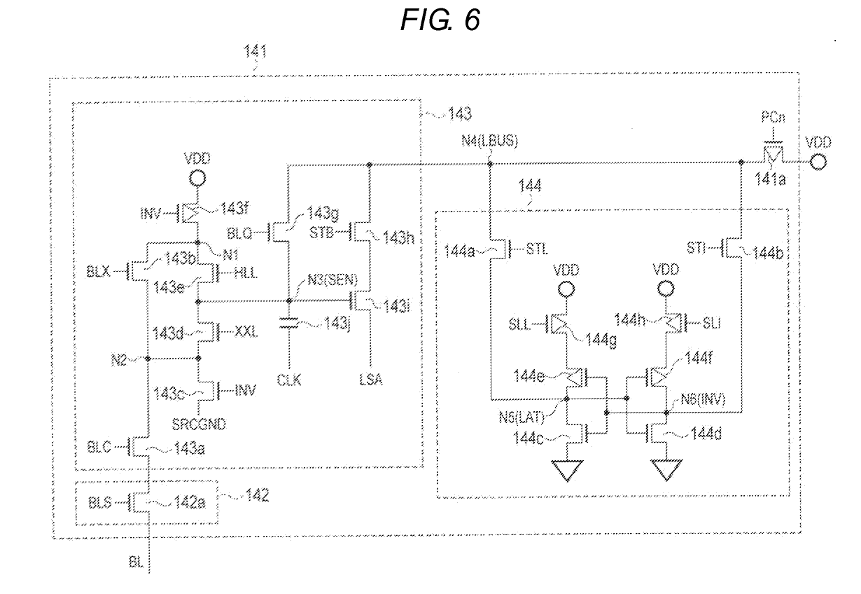

Next, with reference to FIG. 6, a configuration of a sense module 141 will be described. The sense module 141 is provided for each bit line BL.

As illustrated in FIG. 6, the sense module 141 includes a hookup portion 142, a sense amplifier 143, a data latch 144, and a pMOS transistor 141a.

The hookup portion 142 includes an nMOS transistor 142a. The transistor 142a has a gate to which a signal BLS is input, and a source which is connected to the bit line BL. The transistor 142a is used to control connection between the sense module 141 and the bit line BL.

The sense amplifier 143 includes nMOS transistors 143a, 143b, 143c, 143d, 143e, 143g, 143h, and 143i, a pMOS transistor 143f, and a capacitive element 143j.

The transistor 143a is used to control a precharge potential of the bit line BL during reading data, and has a source which is connected to a drain of the transistor 142a and a gate to which a signal BLC is input. The transistor 143f is used to charge the bit line BL and the capacitive element 143j, and includes a gate which is connected to a node INV and a source to which a power supply voltage VDD is input. The transistor 143b is used to precharge the bit line BL, and includes a gate to which a signal BLX is input, a drain which is connected to a node N1, and a source which is connected to a node N2. The transistor 143e is used to charge the capacitive element 143j, and includes a gate to which a signal HLL is input, a drain which is connected to the node N1, and a source which is connected to a node N3 (SEN). The transistor 143d is used to discharge the node N3 (SEN) during a sensing operation, and includes a gate to which a signal XXL is input, a drain which is connected to the node N3 (SEN), and a source which is connected to the node N2. The transistor 143c is used to fix the bit line BL to a specific voltage, and has a gate which is connected to the node INV, a drain which is connected to the node N2, and a source which is connected to a node SRCGND.

The capacitive element 143j is charged during precharging the bit line BL, and has one electrode connected to the node N3 (SEN) and the other electrode to which a signal CLK is input.

The transistor 143g is used to discharge the node N3 (SEN) before the sensing operation is performed, and includes a gate to which a signal BLQ is input, a source connected to the node N3 (SEN), and a drain connected to a node N4 (LBUS). The node N4 (LBUS) is a signal path for connecting the sense amplifier 143 and the data latch 144 to each other. The transistor 143h is used to store read data in the data latch 144, and includes a gate to which a signal STB is input and a drain connected to the node N4 (LBUS).

The transistor 143i is used to sense whether read data is “0” or “1”, has a gate connected to the node N3 (SEN), a drain connected to the source of the transistor 143h, and a source to which a signal LSA is input.

Next, the data latch 144 will be described. The data latch 144 holds read data which is sensed by the sense amplifier 143. The data latch 144 includes nMOS transistors 144a, 144b, 144c and 144d, and pMOS transistors 144e, 144f, 144g and 144h.

The transistors 144c and 144e form a first inverter, and an output node thereof is a node N5 (LAT), and an input node thereof is a node N6 (INV). The transistors 144d and 144f form a second inverter, and an output node thereof is the node N6 (INV), and an input node thereof is the node N5 (LAT). The data latch 144 holds data with the first and second inverters.

In other words, the transistor 144c includes a drain connected to the node N5 (LAT), a source connected to the ground, and a gate connected to the node N6 (INV). The transistor 144d includes a drain connected to the node N6 (INV), a source connected to the ground, and a gate connected to the node N5 (LAT). The transistor 144e includes a drain connected to the node N5 (LAT), a source connected to a drain of the transistor 144g, and a gate connected to the node N6 (INV). The transistor 144f includes a drain connected to the node N6 (INV), a source connected to a drain of the transistor 144h, and a gate connected to the node N5 (LAT).

The transistor 144g is used to enable the first inverter, and has a source to which the power supply voltage VDD is input and a gate to which a signal SLL is input. The transistor 144h is used to enable the second inverter, and includes a source to which the power supply voltage VDD is input and a gate to which a signal SLI is input.

The transistors 144a and 144b control input and output of data to and from the first and second inverters. The transistor 144a includes a drain connected to the node N4 (LBUS), a source connected to the node N5 (LAT), and a gate to which a signal STL is input. The transistor 144b includes a drain connected to the node N4 (LBUS), a source connected to the node N6 (INV), and a gate to which a signal STI is input.

Next, the transistor 141a will be described. The transistor 141a is used to charge the node N4 (LBUS) to the power supply voltage VDD. In other words, the transistor 141a includes a source to which the power supply voltage VDD is input, a drain connected to the node N4 (LBUS), and a gate to which a signal PCn is input. In the above-described configuration, the various control signals are given by, for example, the sequencer 111.

Operation of Sense Module

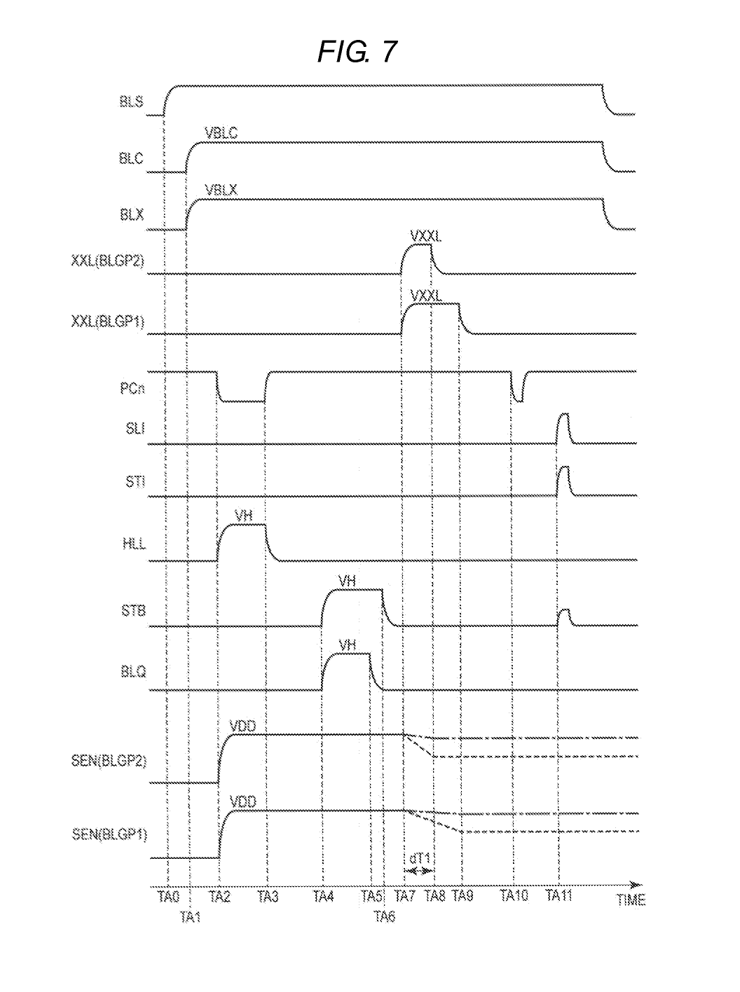

Next, with reference to FIG. 7, a description will be made of an operation of the sense module according to the present embodiment during reading data. The sequencer 111 of the present embodiment changes a timing for performing a sensing operation of the first group bit line BLGP1 and a timing for performing a sensing operation of the second group bit line BLGP2. Hereinafter, a detailed description will be made of an operation of the sense module 141 during reading data. In addition, each signal is given by, for example, the sequencer 111.

Time Point TA0

At the time point TA0, the sequencer 111 generates the signal BLS with an “H” level so as to connect the sense module 141 to a corresponding bit line BL. In addition, the node INV is reset to an “L” level.

Time Point TA1

The sense module 141 precharges the bit line BL. In other words, the sequencer 111 sets the signals BLX and BLC to an “H” level. Consequently, the bit line BL is precharged to the voltage VDD via current paths of the transistors 143f, 143b, 143a and 142a. A voltage VBLC is a voltage for determining a bit line voltage, and the bit line voltage is a voltage VBL which is a voltage clamped by the voltage VBLC.

Time Point TA2

Next, the sense module 141 charges the node N3 (SEN). In other words, the sequencer 111 sets the signal HLL to an “H” level. Consequently, the transistor 143e is turned on, and the node N3 (SEN) is charged to the voltage VDD. The charging of the node N3 (SEN) is performed up to the time point TA3. If a potential of the node N3 (SEN) becomes VDD, the transistor 143i is turned on. In addition, the sense module 141 charges the node N4 (LBUS). In other words, the sequencer 111 sets the signal PCn to an “L” level. Consequently, the transistor 141a is turned on, and thus the node N4 (LBUS) is charged to the voltage VDD.

Time Point TA4

Next, the sense module 141 discharges the node N3 (SEN) which is charged to VDD. In other words, the sequencer 111 sets the signals STB and BLQ to an “H” level (a voltage VH). Consequently, the transistors 143h and 143g are turned on, and thus the potential of the node N3 (SEN) is discharged to (VLSA+Vthn) via current paths of the transistors 143g, 143h and 143i. Further, Vthn indicates a threshold voltage of the transistor 143i.

Time Point TA5

The sequencer 111 sets the signal BLQ to an “L” level. Consequently, the transistor 143g is turned off.

Time Point TA6

The sequencer 111 sets the signal STB to an “L” level. Consequently, the transistor 143h is turned off.

Time Point TA7 to Time Point TA9

Next, the sense module 141 performs a sensing operation on the first group bit line BLGP1 and the second group bit line BLGP2. In the present embodiment, the sensing operation indicates an operation of changing a potential of the node N3 (SEN) in order to read data of a selected memory cell transistor.

The sequencer 111 sets the signal XXL of the sense module 141 to an “H” level at the time point TA7. Consequently, the transistor 143d is turned on, and thus the node N3 (SEN) is electrically connected to the bit line BL. For example, if a selected memory cell transistor is turned on, a current flows from the node N3 (SEN) to the source line SL, and thus a potential of the node N3 (SEN) is reduced. On the other hand, if the selected memory cell transistor is turned off, a current does not flow from the node N3 (SEN) to the source line SL, and thus a potential of the node N3 (SEN) is maintained to be VDD. A current which flows through the bit line BL is referred to as a cell current or the like. Hereinafter, a potential state of the node N3 (SEN) when a bit line BL cell current flows is referred to as a sensing result or the like.

The capacitance of the second group bit line BLGP2 is smaller than the capacitance of the first group bit line BLGP1. For this reason, if a selected memory cell transistor is turned on, a potential of the node N3 (SEN) of the sense module 141 connected to the first group bit line BLGP1 is not lower than a potential of the node N3 (SEN) of the sense module 141 connected to the second group bit line BLGP2. In other words, if a selected memory cell transistor is turned on, there occurs a variation between a sensing result of the first group bit line BLGP1 and a sensing result of the second group bit line BLGP2.

Therefore, the sequencer 111 according to the present embodiment controls a timing of the signal XXL related to the second group bit line BLGP2 so that a reduction in a potential of the node N3 (SEN) related to the second group bit line BLGP2 is substantially the same as a reduction in a potential of the node N3 (SEN) related to the first group bit line BLGP1 when a selected memory cell transistor is turned on.

At the time point TA8 after the time dT1 has elapsed from the time point TA7, the sequencer 111 sets the signal XXL of the sense module 141 connected to the second group bit line BLGP2 to an “L” level earlier than the signal XXL of the sense module 141 connected to the first group bit line BLGP1.

Next, at the time point TA9, the sequencer 111 sets the signal XXL of the sense module 141 connected to the first group bit line BLGP1 to an “L” level.

The time dT1 is appropriately set in consideration of a difference between the capacitance of the first group bit line BLGP1 and the capacitance of the second group bit line BLGP2, and is stored in a ROM fuse region (not illustrated) or the like provided in the memory cell array 130. In addition, during starting the memory system 1, the time dT1 is read to, for example, the register 113. The sequencer 111 refers to the register 113 in order to refer to the time dT1.

Time Point TA10

Next, the sense module 141 charges the node N4 (LBUS). In other words, the sequencer 111 sets the signal PCn to an “L” level. Consequently, the transistor 141a is turned on, and thus the node N4 (LBUS) is charged to VDD via the transistor 141a.

Time Point TA11

The sense module 141 performs strobe of data. In other words, the sequencer 111 sets the signal STB to an “H” level, the signal SLI to an “L” level, and the signal STI to the “H” level. Consequently, the transistors 143h, 144f and 144b are turned on. If the transistor 143i is turned on (that is, SEN=“H”), the node N4 (LBUS) is discharged nearly to VSS, and thus an “L” level is stored in the node INV. If the transistor 143i is turned off (that is, SEN=“L”), a potential of the node N4 (LBUS) is maintained to be VDD, and thus an “H” level is stored in the node INV.

### Operations and Effects According to First Embodiment

According to the above-described embodiment, an operation of the sense circuit is controlled according to parasitic capacitance caused by the arrangement of the semiconductor pillars SP. As described above, a degree of the reduction in a potential of the node N3 (SEN) is changed depending on the capacitance of the semiconductor pillar SP when a selected memory cell transistor is turned on. Therefore, the sequencer 111 stops a cell current in a bit line connected to the semiconductor pillar SP with a small capacitance earlier than in a bit line connected to the semiconductor pillar SP with a large capacitance. Consequently, a variation in a sensing result caused by a capacitance variation of the semiconductor pillar SP may be suppressed. As a result, even if there is a capacitance variation of the semiconductor pillar SP, a sensing operation may be performed with high accuracy.

### First Modification Example

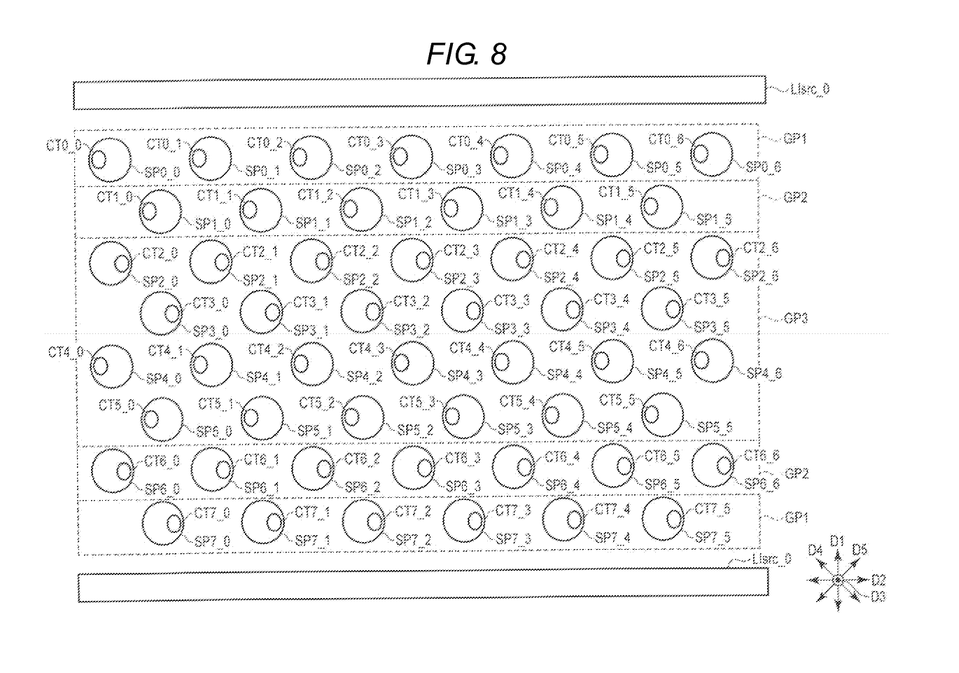

In the above-described first embodiment, a configuration is described in which four semiconductor pillar SP groups including the semiconductor pillar SP0 group (SP0_0, SP0_1, . . . ), the semiconductor pillar SP1 group (SP1_0, SP1_1, . . . ), the semiconductor pillar SP2 group (SP2_0, SP2_1, . . . ), and the semiconductor pillar SP3 group (SP3_0, SP3_1, . . . ) are provided between the two source line contacts LIsrc in a predetermined block BLK of the memory cell array 130. However, the first embodiment is not limited thereto, and, as illustrated in FIG. 8, eight semiconductor pillar SP groups including the semiconductor pillar SP0 group (SP0_0, SP0_1, . . . ), the semiconductor pillar SP1 group (SP1_0, SP1_1, . . . ), the semiconductor pillar SP2 group (SP2_0, SP2_1, . . . ), the semiconductor pillar SP3 group (SP3_0, SP3_1, . . . ), semiconductor pillar SP4 group (SP4_0, SP4_1, . . . ), the semiconductor pillar SP5 group (SP5_0, SP5_1, . . . ), the semiconductor pillar SP6 group (SP6_0, SP6_1, . . . ), and the semiconductor pillar SP7 group (SP7_0, SP7_1, . . . ) are provided between the two source line contacts LIsrc in a predetermined block BLK of the memory cell array 130.

For example, the semiconductor pillar SP0 group and the semiconductor pillar SP7 group may be classified into a first group GP1, the semiconductor pillar SP2 group and the semiconductor pillar SP6 group may be classified into a second group GP2, and the semiconductor pillar SP3 group to the semiconductor pillar SP5 group may be classified into a third group GP3.

More specifically, the semiconductor pillar SP0 group and the semiconductor pillar SP7 group are defined as a first semiconductor pillar group SPGP1 included in the first group GP1. In addition, the semiconductor pillar SP2 group and the semiconductor pillar SP6 group are defined as a second semiconductor pillar group SPGP2 included in the second group GP2. Further, the semiconductor pillar SP3 group to the semiconductor pillar SP5 group are defined as a third semiconductor pillar group SPGP3 included in the third group GP3.

The bit lines BL connected to the first semiconductor pillar group SPGP1 are also referred to as a first group bit line BLGP1 or the like. The bit lines BL connected to the second semiconductor pillar group SPGP2 are also referred to as a second group bit line BLGP2 or the like. The bit lines BL connected to the third semiconductor pillar group SPGP3 are also referred to as a third group bit line BLGP3.

Bit line capacitances of the first group bit line BLGP1, the second group bit line BLGP2, and the third group bit line BLGP3 may be different from each other depending on a position of each of the plurality of semiconductor pillars SP and a position between the semiconductor pillar SP and the source line contact LIsrc. The semiconductor pillar SP2_3 included in the third group GP3 may be influenced by a total of twelve semiconductor pillars including the semiconductor pillars SP0_3, SP1_1, SP1_2, SP1_3, SP1_4, SP2_2, SP2_4, SP3_1, SP3_2, SP3_3, SP3_4 and SP4_3. In addition, the semiconductor pillar SP1_3 included in the second group GP2 may be influenced by a total of eleven semiconductor pillars including the semiconductor pillars SP0_2, SP0_3, SP0_4, SP0_5, SP1_2, SP1_4, SP2_2, SP2_3, SP2_4, SP2_5, and SP3_3. Further, the semiconductor pillar SP0_3 included in the first group GP1 may be influenced by a total of seven semiconductor pillars including the semiconductor pillars SP0_2, SP0_4, SP1_1, SP1_2, SP1_3, SP1_4 and SP2_3, and the source line contact LIsrc_0.

Hereinafter, for simplification, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

The sequencer 111 may apply the operation of the sense circuit described in the first embodiment in accordance with the first group bit line BLGP1 to the third group bit line BLGP3.

### Operation of Sense Module According to the First Modification Example

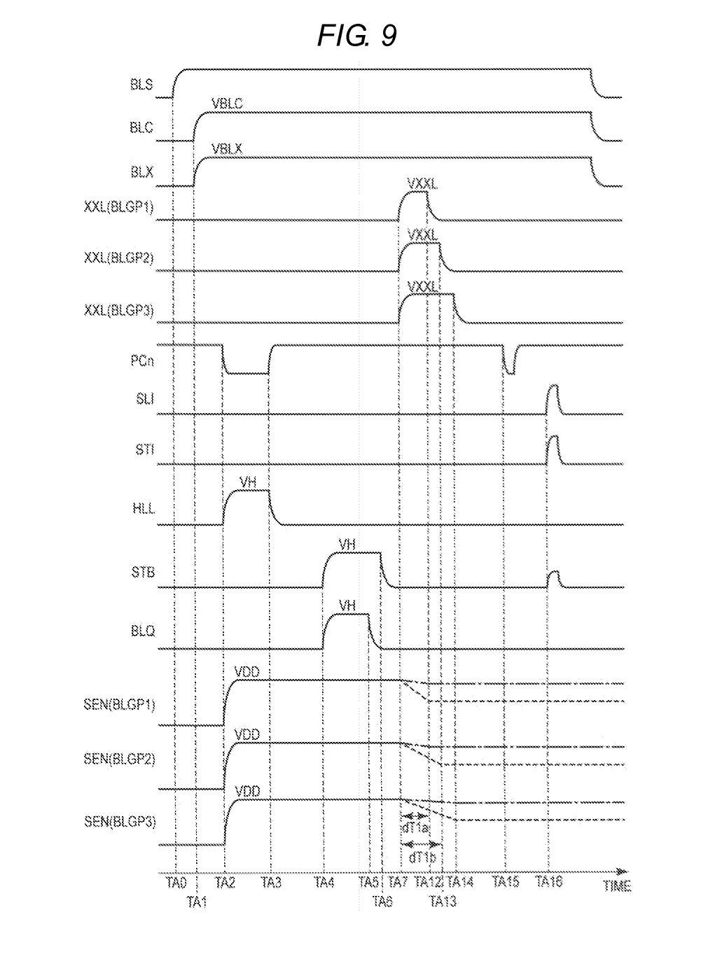

With reference to FIG. 9, a description will be made of a case where the present modification example is applied to an operation of the sense module of the first embodiment.

Time Point TA0 to Time Point TA6

At the time point TA0 to the time point TA6, the sequencer 111 performs the same operations as the operations at the time points TA0 to TA6 described in the first embodiment.

Time Point TA7, and Time Point TA12 to Time Point TA14

Next, the sense module 141 performs a sensing operation on the first group bit line BLGP1, the second group bit line BLGP2, and the third group bit line BLGP3. In other words, the sequencer 111 sets the signal XXL of the sense module 141 to an “H” level at the time point TA7.

The capacitances of the first group bit line BLGP1 to the third group bit line BLGP3 are different from each other. As described in the first embodiment, if a selected memory cell transistor is turned on, there are variations between a sensing result of the first group bit line BLGP1, a sensing result of the second group bit line BLGP2, and a sensing result of the third group bit line BLGP3.

Therefore, the sequencer 111 according to the present modification example controls timings of the signal XXL related to the first group bit line BLGP1 and the second group bit line BLGP2 so that a reduction in a potential of the node N3 (SEN) related to the first group bit line BLGP1 and a reduction in a potential of the node N3 (SEN) related to the second group bit line BLGP2 are substantially the same as a reduction in a potential of the node N3 (SEN) related to the third group bit line BLGP3 when a selected memory cell transistor is turned on.

At the time point TA12 after the time dT1a has elapsed from the time point TA7, the sequencer 111 sets the signal XXL of the sense module 141 connected to the first group bit line BLGP1 to an “L” level.

Subsequently, at the time point TA13 after the time dT1b (dT1a<dT1b) has elapsed from the time point TA7, the sequencer 111 sets the signal XXL of the sense module 141 connected to the second group bit line BLGP2 to an “L” level.

Further, at the time point TA14 the sequencer 111 sets the signal XXL of the sense module 141 connected to the third group bit line BLGP3 to an “L” level.

The time dT1a and the time dT1b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the time dT1a and the time dT1b are read to, for example, the register 113. The sequencer 111 refers to the register 113 in order to refer to the time dT1a and the time dT1b.

Time Point TA15 and Time Point TA16

Next, at the time point TA15 and the time point TA16, the sequencer 111 performs the same operations as the operations at the time points TA10 and TA11 described in the first embodiment.

As mentioned above, the sequencer 111 controls an end timing of the sensing operation according to the capacitance of the bit line BL and may thus suppress a variation in a sensing result caused by the capacitance of the bit line BL.

In the present modification example, the semiconductor pillars are classified into three groups, and the sequencer 111 controls timings at which sensing operations of the bit lines of the three groups end. However, the present modification example is not limited thereto, and the semiconductor pillars may be classified into four or more groups. In addition, information regarding timings at which sensing operations of the bit lines of the four or more groups end may be stored in the ROM fuse region (not illustrated) provided in the memory cell array 130. Consequently, the sequencer 111 may control timings at which sensing operations of the bit lines of the four or more groups end.

### Second Embodiment

Next, a second embodiment will be described. In the second embodiment, an operation of a sense module is different from the operation of the sense module according to the first embodiment. In addition, a fundamental configuration and a fundamental operation of the memory device according to the second embodiment are the same as those of the memory device according to the first embodiment. Therefore, description of the content described in the first embodiment and content which may be easily analogized from the first embodiment will be omitted.

### Operation of Sense Module According to Second Embodiment

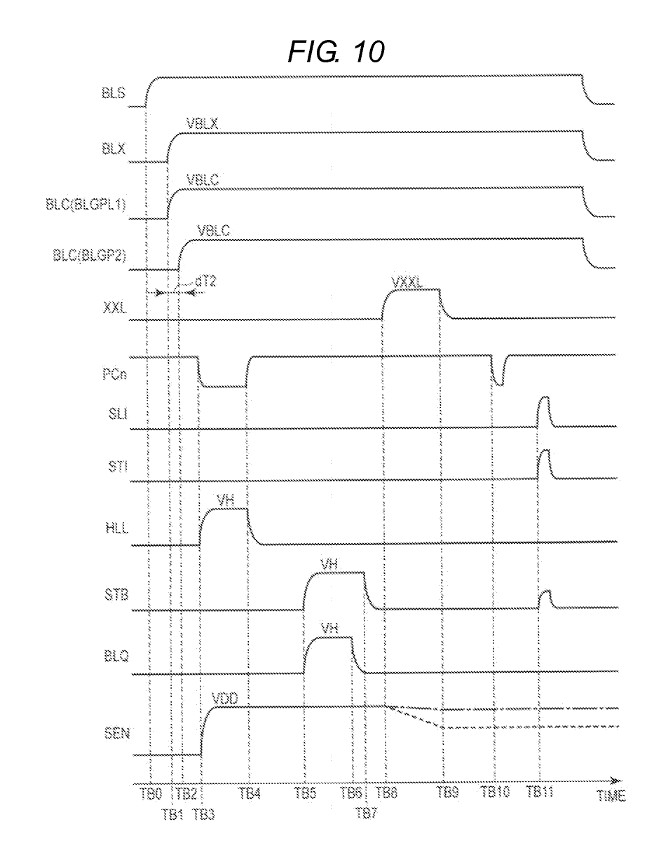

With reference to FIG. 10, a description will be made of an operation of the sense module according to the second embodiment during reading data. The sequencer 111 of the present embodiment changes a timing for performing precharge of the first group bit line BLGP1 and a timing for performing precharge of the second group bit line BLGP2. Hereinafter, a detailed description will be made of an operation of the sense module 141 during reading data. In the same manner as in the first embodiment, hereinafter, a description will be made of a case where a capacitance of the first group bit line BLGP1 is larger than a capacitance of the second group bit line BLGP2. In addition, each signal is given by, for example, the sequencer 111.

Time Point TB0

The sequencer 111 performs the same operation as the operation at the time point TA0 described in the first embodiment.

Time Point TB1 and Time Point TB2

The sense module 141 precharges the bit line BL. However, the time required for the precharge is changed depending on a capacitance of the bit line. Specifically, the time required to precharge the first group bit line BLGP1 is longer than the time required to precharge the second group bit line BLGP2. Therefore, the sense module 141 according to the present embodiment precharges the first group bit line BLGP1 earlier than the second group bit line BLGP2.

At the time point TB1, the sequencer 111 sets the signal BLX to an “H” level. In addition, the sequencer 111 sets the signal BLC related to the sense module 141 connected to the first group bit line BLGP1 to an “H” level. Consequently, the first group bit line BLGP1 is precharged to the voltage VDD via current paths of the transistors 143f, 14be, 143a and 142a related to the sense module 141 connected to the first group bit line BLGP1. A voltage VBLC is a voltage for determining a bit line voltage.

In addition, at the time point TB2 after the time dT2 has elapsed from the time point TB1, the sequencer 111 sets the signal BLC related to the sense module 141 connected to the second group bit line BLGP2 to an “H” level. Consequently, the second group bit line BLGP2 is precharged to the voltage VDD via current paths of the transistors 143f, 143b, 143a and 142a related to the sense module 141 connected to the second group bit line BLGP2.

The time dT2 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the time dT2 is read to, for example, the register 113. The sequencer 111 refers to the register 113 in order to refer to the time dT2.

As mentioned above, a timing for performing precharge is controlled in consideration of the capacitance of the bit line, and thus a variation between the time at which precharge of the first group bit line BLGP1 is completed and the time at which precharge of the second group bit line BLGP2 is completed may be suppressed.

Time Point TB3 to Time Point TB7

The sequencer 111 performs the same operations as the operations at the time point TA2 to the time point TA6 described in the first embodiment.

Time Point TB8

Next, the sense module 141 performs a sensing operation on the bit line BL. In other words, the sequencer 111 sets the signal XXL of the sense module 141 to an “H” level. Consequently, the transistor 143d is turned on, and thus the node N3 (SEN) is electrically connected to the bit line BL.

Time Point TB9

Next, the sequencer 111 sets the signal XXL of the sense module 141 connected to the first group bit line BLGP1 to an “L” level.

Time Point TB10 and Time Point TB11

The sequencer 111 performs the same operations as the operations at the time point TA10 and the time point TA11 described in the first embodiment.

### Operation and Effect According to Second Embodiment

According to the above-described embodiment, the sequencer controls a precharge timing of the bit line according to parasitic capacitance caused by the arrangement of the semiconductor pillars SP. Consequently, it is possible to suppress a variation in the time to complete precharge each bit line, caused by a capacitance variation of the semiconductor pillar SP.

### Second Modification Example

In the same manner as in the modification example of the first embodiment, the operation of the sense module of the second embodiment may also be applied to a case where there are three or more semiconductor pillar groups.

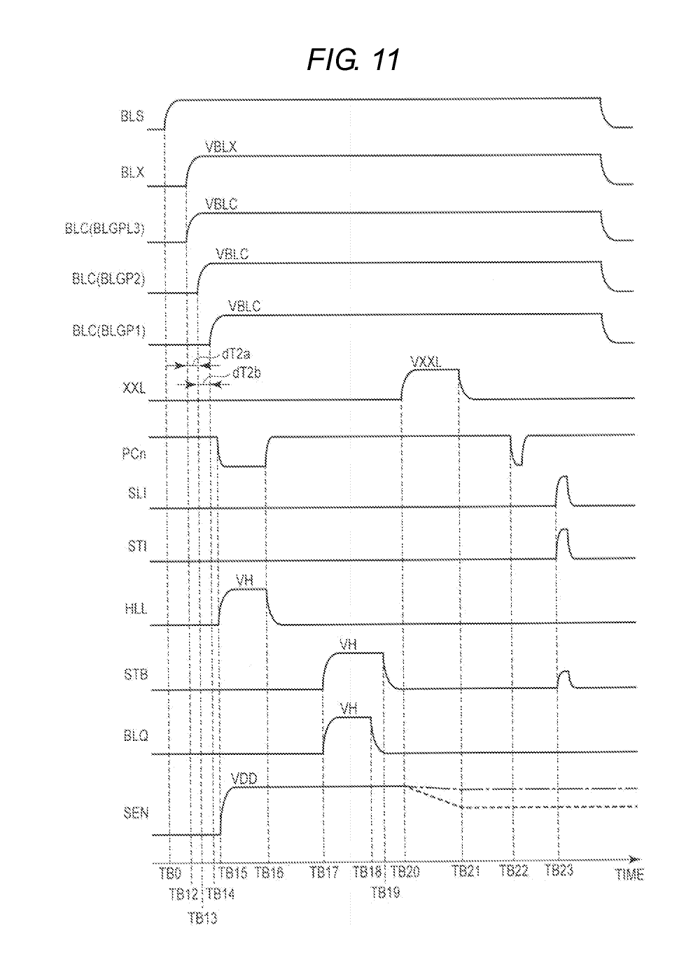

With reference to FIG. 11, a description will be made of a case where the configuration described in FIG. 8 is applied to an operation of the sense module of the second embodiment.

### Operation of Sense Module According to the Second Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TB0

At the time point TA0, the sequencer 111 performs the same operation as the operation at the time point TA0 described in the first embodiment.

Time Point TB12, Time Point TB13, and Time Point TB14

The sense module 141 precharges the bit line BL. However, the time required for the precharge is changed depending on a capacitance of the bit line. Specifically, the time required to precharge the third group bit line BLGP3 is longer than the time required to precharge the second group bit line BLGP2. In addition, the time required to precharge the second group bit line BLGP2 is longer than the time required to precharge the first group bit line BLGP1. Therefore, the sense module 141 according to the present embodiment precharges the third group bit line BLGP3 earlier than the first group bit line BLGP1 and the second group bit line BLGP2. In addition, the sense module 141 according to the present embodiment precharges the second group bit line BLGP2 earlier than the first group bit line BLGP1.

At the time point TB12, the sequencer 111 sets the signal BLX to an “H” level. In addition, the sequencer 111 sets the signal BLC related to the sense module 141 connected to the third group bit line BLGP3 to an “H” level. Consequently, the third group bit line BLGP3 is precharged to the voltage VDD via current paths of the transistors 143f, 143e, 143a and 142a related to the sense module 141 connected to the third group bit line BLGP3. A voltage VBLC is a voltage for determining a bit line voltage, and the bit line voltage is a voltage VBL which is clamped by the voltage VBLC.

In addition, at the time point TB13 after the time dT2a has elapsed from the time point TB12, the sequencer 111 sets the signal BLC related to the sense module 141 connected to the second group bit line BLGP2 to an “H” level. Consequently, the second group bit line BLGP2 is precharged to the voltage VDD via current paths of the transistors 143f, 143e, 143a and 142a related to the sense module 141 connected to the second group bit line BLGP2.

In addition, at the time point TB14 after the time dT2b has elapsed from the time point TB13, the sequencer 111 sets the signal BLC related to the sense module 141 connected to the first group bit line BLGP1 to an “H” level. Consequently, the first group bit line BLGP1 is precharged to the voltage VDD via current paths of the transistors 143f, 143e, 143a and 142a related to the sense module 141 connected to the first group bit line BLGP1.

The time dT2a and the time dT2b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the time dT2a and the time dT2b are read to, for example, the register 113. The sequencer 111 refers to the register 113 in order to refer to the time dT2a and the time dT2b.

Time Point TB15 to Time Point TB23

The sequencer 111 performs the same operations as the operations at the time points TB3 to TB11 described in the second embodiment.

As mentioned above, the precharge is performed in consideration of the capacitance of the bit line, and thus a variation between the time to complete precharge of the first group bit line BLGP1, the time to complete precharge of the second group bit line BLGP2, and the time to complete precharge of the third group bit line BLGP3 may be suppressed.

In the present modification example, semiconductor pillars are classified into three groups, and the sequencer 111 controls timings for performing precharge of the bit lines of the three groups. However, the present modification example is not limited thereto, and the semiconductor pillars may be classified into four or more groups. In addition, information regarding timings for precharging the bit lines of the four or more groups may be stored in the ROM fuse region (not illustrated) provided in the memory cell array 130. Consequently, the sequencer 111 may control timings for precharging the bit lines of the four or more groups.

### Third Embodiment

Next, a third embodiment will be described. In a semiconductor memory device according to the third embodiment, a sense circuit is different from the sense circuit according to the first embodiment. In addition, a fundamental configuration and a fundamental operation of the memory device according to the third embodiment are the same as those of the memory device according to the first embodiment. Therefore, description of the content described in the first embodiment and content which may be easily analogized from the first embodiment will be omitted. In the first and second embodiments, the description has been made by exemplifying a current sensing method. However, the sense circuit 140 according to the first and second embodiments may be applied to a sense amplifier of a voltage sensing method. In the voltage sensing method, the sense circuit 140 changes a potential of a bit line according to read data, and detects the voltage change by using the transistor 143i. The potential change of the bit line influences a potential of the adjacent bit line due to capacitive coupling between the bit lines. As a result, there is a concern that a data reading error may occur. Therefore, in the voltage sensing method, unlike the current sensing method in which data may be simultaneously read from all the bit lines, data is read every even-numbered bit line and is read every odd-numbered bit line.

### Summary of Sensing Operation According to Third Embodiment

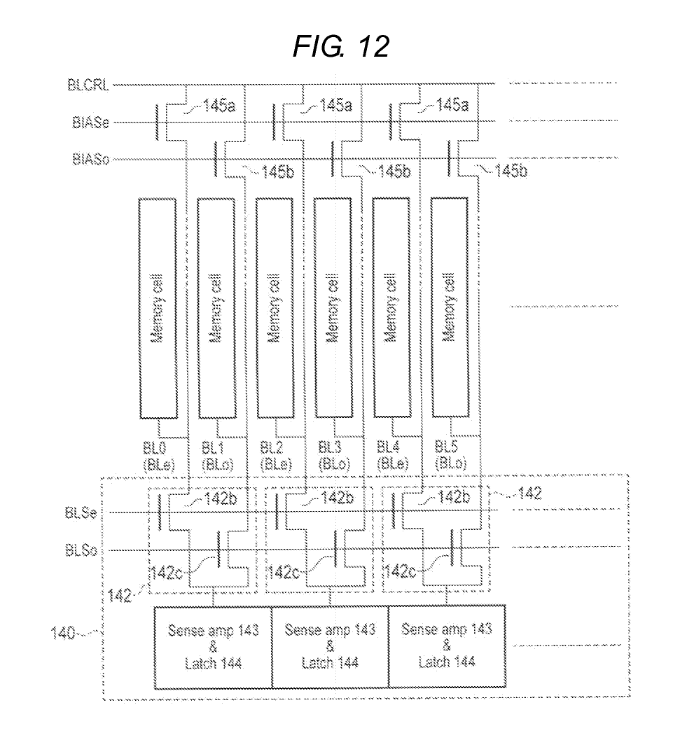

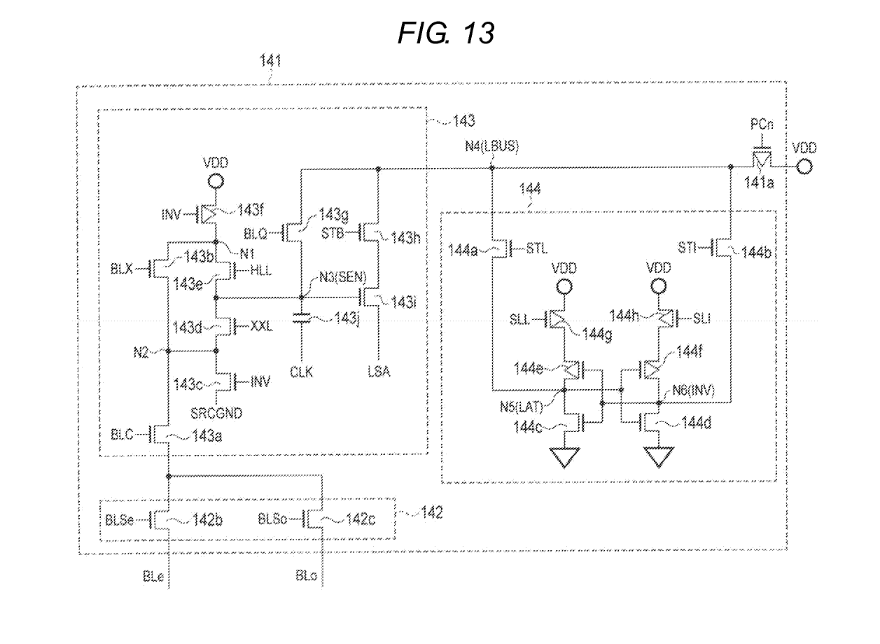

As illustrated in FIG. 12, when the sense circuit 140 which performs a sensing operation by using the voltage sensing method performs on a certain bit line, the sensing operation is performed by shielding bit lines adjacent to each other. In other words, in the voltage sensing method, a voltage change of the bit line is sensed. As mentioned above, in the voltage sensing method, data is read every even-numbered bit line and every odd-numbered bit line. When data is read from the even-numbered bit line, the odd-numbered bit line is fixed to a specific potential (is shielded), and when data is read from the odd-numbered bit line, the even-numbered bit line is fixed to a specific potential.

In the present embodiment, two bit lines adjacent to each other are classified into an even-numbered bit line BLe and an odd-numbered bit line BLo. The even-numbered bit line BLe and the odd-numbered bit line BLo adjacent to each other share a single sense module 141.

In the present embodiment, if data is read from the even-numbered bit line BLe, the sequencer 111 turns on the transistor 142b for the even-numbered bit line BLe, so that the even-numbered bit line BLe is connected to the sense amplifier 143. In this case, the sequencer 111 sets a signal BIASo to an “H” level, and thus a ground transistor 145b is turned on. Consequently, a ground potential BLCRL is applied to the odd-numbered bit line BLo, and thus the odd-numbered bit line BLo has a predetermined potential (the ground potential in the present embodiment).

The sense module 141 precharges the even-numbered bit line BLe in a state in which the odd-numbered bit line BLo has the ground potential. In this case, a potential of the odd-numbered bit line BLo is maintained to be the predetermined potential. For this reason, the even-numbered bit line BLe is appropriately precharged without being influenced by a potential change of the odd-numbered bit line BLo.

On the other hand, if data is read from the odd-numbered bit line, the sequencer 111 turns on the transistor 142c for the odd-numbered bit line BLo, so that the odd-numbered bit line BLo is connected to the sense amplifier 143. In this case, the sequencer 111 sets a signal BIASe to an “H” level and thus turns on a ground transistor 145a. Consequently, the ground potential BLCRL is applied to the even-numbered bit line BLe, and thus the even-numbered bit line BLe has a predetermined potential (the ground potential in the present embodiment).

The sense module 141 precharges the odd-numbered bit line BLo in a state in which the even-numbered bit line BLe has the ground potential. In this case, the odd-numbered bit line BLo is appropriately precharged as described above.

As mentioned above, during the reading operation, an unselected bit line is grounded, and thus an accurate reading operation may be performed without being influenced by a signal of the unselected bit line.

### Sense Module According to Third Embodiment

Next, with reference to FIG. 13, a configuration of the sense module 141 will be described. As illustrated in FIG. 13, in the same manner as the sense module 141 according to the first embodiment, the sense module 141 according to the third embodiment includes a hookup portion 142, a sense amplifier 143, a data latch 144, and a pMOS transistor 141a.

The hookup portion 142 includes nMOS transistor 142b and 142c. The transistor 142b includes a gate to which a signal BLSe is input, and a source which is connected to the even-numbered bit line BLe. The transistor 142c includes a gate to which a signal BLSo is input, and a source which is connected to the odd-numbered bit line BLo. The transistor 142b is used to control connection between the sense module 141 and the even-numbered bit line BLe. The transistor 142c is used to control connection between the sense module 141 and the odd-numbered bit line BLo.

In addition, configurations of the sense amplifier 143, the data latch 144, and the pMOS transistor 141a are the same as the configurations of the sense amplifier 143, the data latch 144, and the pMOS transistor 141a according to the first embodiment.

### Operation of Sense Module According to Third Embodiment

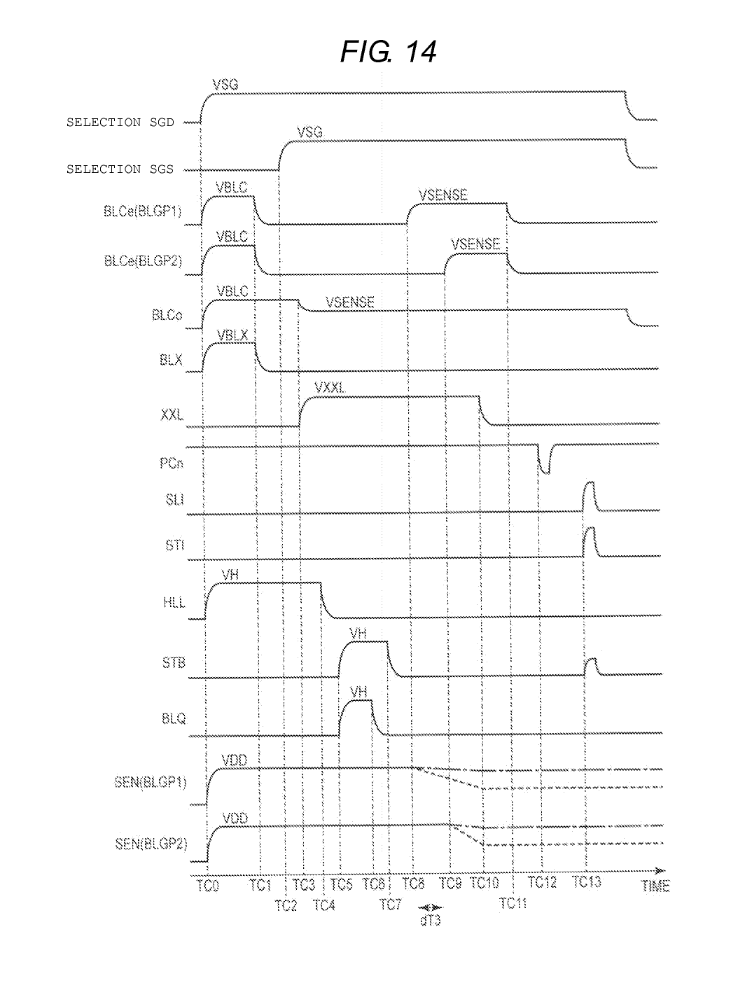

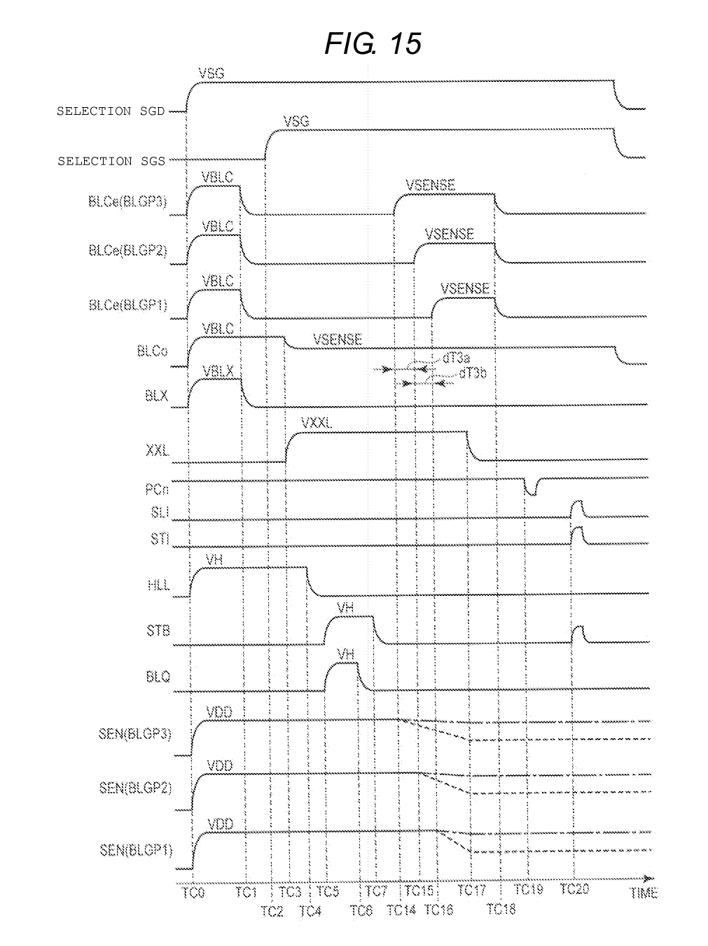

Next, with reference to FIG. 14, a description will be made of an operation of the sense module according to the third embodiment during reading data. The sequencer 111 of the present embodiment shifts a timing for performing a sensing operation of the first group bit line BLGP1 and a timing for performing a sensing operation of the second group bit line BLGP2. Hereinafter, a description will be made of an operation when an even-numbered bit line is selected, and an odd-numbered bit line is unselected. In the same manner as in the first embodiment, hereinafter, a description will be made of a case where a capacitance of the first group bit line BLGP1 is larger than a capacitance of the second group bit line BLGP2. In addition, each signal is given by, for example, the sequencer 111.

Time Point TC0

As illustrated in FIG. 14, the sequencer 111 sets a signal BLCe for the even-numbered bit line BLe and a signal BLCo for the odd-numbered bit line BLo to an “H” level (voltage VBLC). At the same time, the sequencer 111 sets the signals BLX and HLL to an “H” level. In addition, the sequencer 111 sets the drain side gate line SGD of a selected string to an “H” level (VSG). Further, the sequencer 111 sets the node INV to an “L” level with respect to the even-numbered bit line BLe, and sets the signal BIASe of the transistor 145a to an “L” level. In addition, the sequencer 111 sets the node INV to an “H” level with respect to the odd-numbered bit line BLo, and sets the signal BIASo of the transistor 145b to an “H” level.

As a result, the even-numbered bit line BLe is precharged to a voltage (VBLC-Vt), and the voltage VSS is applied to the odd-numbered bit line BLo. Vt indicates a threshold voltage of the transistor 143i. In addition, the node SEN is charged to the voltage VDD. Further, a voltage VBB is applied to the selection gate line SGD of an unselected string. Each signal is given by, for example, the sequencer 111.

Time Point TC1

Next, the sequencer 111 sets the signals BLCe and BLX to an “L” level. Consequently, the precharge of the even-numbered bit line BLe is finished, and the even-numbered bit line BLe is in a floating state at the voltage (VBLC−Vt).

Time Point TC2

Next, the sequencer 111 sets the source side selection gate line SGS of a selected string to an “H” level (VSG). Consequently, if a cell current (ON current) flows in the selected string, the even-numbered bit line BLe is discharged. The voltage VBB is applied to the source side selection gate line SGS of an unselected string. The odd-numbered bit line BLo is maintained to be the voltage VSS.

Time Point TC3

The sequencer 111 reduces a potential of the signal BLCo from the voltage VBLC to the voltage VSENSE, and sets the signal XXL to an “H” level (VXXL).

Time Point TC4

The sequencer 111 sets the signal HLL to an “L” level.

Time Point TC5

Next, the sequencer 111 sets the signals STB and BLQ to an “H” level (VH). As a result, a potential of the node N3 (SEN) is discharged to (VLSA+Vthn).

Time Point TC6

Next, the sequencer 111 sets the signal BLQ to an “L” level in order to finish the discharge of the node N3 (SEN).

Time Point TC7

Next, the sequencer 111 sets the signal STB to an “L” level.

Time Point TC8 to Time Point TC9

The capacitance of the first group bit line BLGP1 is larger than the capacitance of the second group bit line BLGP2. For this reason, the time required for a sensing operation of the first group bit line BLGP1 is longer than the time required for a sensing operation of the second group bit line BLGP2.

The sequencer 111 according to the present embodiment starts a sensing operation on the first group bit line BLGP1 earlier than that on the second group bit line BLGP2. Specifically, at the time point TC8, the sequencer 111 according to the present embodiment sets the signal BLCe of the sense module 141 connected to the even-numbered bit line BLe of the first group bit line BLGP1 to an “H” level (VSENSE). If a selected memory cell is turned on, and thus the even-numbered bit line BLe of the first group bit line BLGP1 is discharged, a potential of the node N3 (SEN) is also reduced. On the other hand, if the selected memory cell is turned off, the even-numbered bit line BLe of the first group bit line BLGP1 is maintained nearly to have the precharge voltage, and thus the potential of the node N3 (SEN) is not changed much.

Subsequently, at the time point TC9 after the time dT3 has elapsed from the time point TC8, the sequencer 111 according to the present embodiment sets the signal BLCe of the sense module 141 connected to the even-numbered bit line BLe of the second group bit line BLGP2 to an “H” level (VSENSE). Consequently, a sensing operation on the second group bit line BLGP2 is started.

The time dT3 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the time dT3 is read to, for example, the register 113. The sequencer 111 refers to the register 113 in order to refer to the time dT3.

Time Point TC10

The sequencer 111 sets the signal XXL to an “L” level, so as to finish the sensing operation.

Time Point TC11

The sequencer 111 sets the signal BLCe to an “L” level.

Time Point TC12

Next, the sequencer 111 sets the signal PCn to an “L” level so as to charge the node N4 (LBUS).

Time Point TC13

The sequencer 111 sets the signal STB to an “H” level so as to perform strobe of data.

In the above-described manner, data may be read from the even-numbered bit line. This is also the same for reading data from the odd-numbered bit line.

### Operations and Effects According to Third Embodiment

According to the above-described embodiment, the sequencer changes timings of the sensing operations according to parasitic capacitance caused by a disposition of the semiconductor pillars SP. Consequently, a variation in the time to complete precharge for each bit line, caused by a capacitance variation of the semiconductor pillar SP, may be suppressed. As a result, even if there is a capacitance variation of the semiconductor pillar SP, a sensing operation may be performed with high accuracy.

### Third Modification Example

In the same manner as in the modification example of the first embodiment, the operation of the sense module of the third embodiment may also be applied to a case where there are three or more semiconductor pillar groups.

With reference to FIG. 15, a description will be made of a case where the configuration described in FIG. 8 is applied to an operation of the sense module of the third embodiment.

### Operation of Sense Module According to the Third Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TC0 to Time Point TC7

The sequencer 111 performs the same operations as the operations at the time points TC0 to TC7 described in the third embodiment.

Time Point TC14 to Time Point TC16

The capacitance of the third group bit line BLGP3 is larger than the capacitance of the second group bit line BLGP2, and the capacitance of the second group bit line BLGP2 is larger than the capacitance of the first group bit line BLGP1. For this reason, the time required for a sensing operation of the third group bit line BLGP3 is longer than the time required for a sensing operation of the second group bit line BLGP2. In addition, the time required for a sensing operation of the second group bit line BLGP2 is longer than the time required for a sensing operation of the first group bit line BLGP1.

Therefore, the sequencer 111 starts a sensing operation of the third group bit line BLGP3 earlier than that of the first group bit line BLGP1 and the second group bit line BLGP2. In addition, the sequencer 111 starts a sensing operation on the second group bit line BLGP2 earlier than that of the first group bit line BLGP1.

For this reason, at the time point TC14, the sequencer 111 according to the present embodiment sets the signal BLCe of the sense module 141 connected to the even-numbered bit line BLe of the third group bit line BLGP3 to an “H” level (VSENSE).

Subsequently, at the time point TC15 after the time dT3a has elapsed from the time point TC14, the sequencer 111 according to the present embodiment sets the signal BLCe of the sense module 141 connected to the even-numbered bit line BLe of the second group bit line BLGP2 to an “H” level (VSENSE). Consequently, a sensing operation on the second group bit line BLGP2 is started.

Subsequently, at the time point TC16 after the time dT3b has elapsed from the time point TC15, the sequencer 111 according to the present embodiment sets the signal BLCe of the sense module 141 connected to the even-numbered bit line BLe of the first group bit line BLGP1 to an “H” level (VSENSE). Consequently, a sensing operation on the first group bit line BLGP1 is started.

The time dT3a and the time dT3b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the time dT3a and the time dT3b are read to, for example, the register 113. The sequencer 111 refers to the register 113 in order to refer to the time dT3a and the time dT3b.

Time Point TC17 to Time Point TC20

The sequencer 111 performs the same operations as the operations at the time points TC10 to TC13 described in the third embodiment.

As mentioned above, a sensing operation is performed in consideration of the capacitance of the bit line, and thus a variation between the time required for a sensing operation on the first group bit line BLGP1, the time required for a sensing operation on the second group bit line BLGP2, and the time required for a sensing operation on the third group bit line BLGP3 may be suppressed.

In the present modification example, semiconductor pillars are classified into three groups, and the sequencer 111 controls timings for performing sensing operations on the bit lines of the three groups. However, the present modification example is not limited thereto, and the semiconductor pillars may be classified into four or more groups. In addition, information regarding timings for performing sensing operations on the bit lines of the four or more groups may be stored in the ROM fuse region (not illustrated) provided in the memory cell array 130. Consequently, the sequencer 111 may control timings for performing sensing operations on the bit lines of the four or more groups.

### Fourth Embodiment

Next, a fourth embodiment will be described. In a semiconductor memory device according to the fourth embodiment, an operation of a sense module is different from the operation of the sense module according to the third embodiment. In addition, a fundamental configuration and a fundamental operation of the memory device according to the fourth embodiment are the same as those of the memory device according to the third embodiment. Therefore, description of the content described in the third embodiment and content which may be easily analogized from the third embodiment will be omitted.

### Operation of Sense Module According to Fourth Embodiment

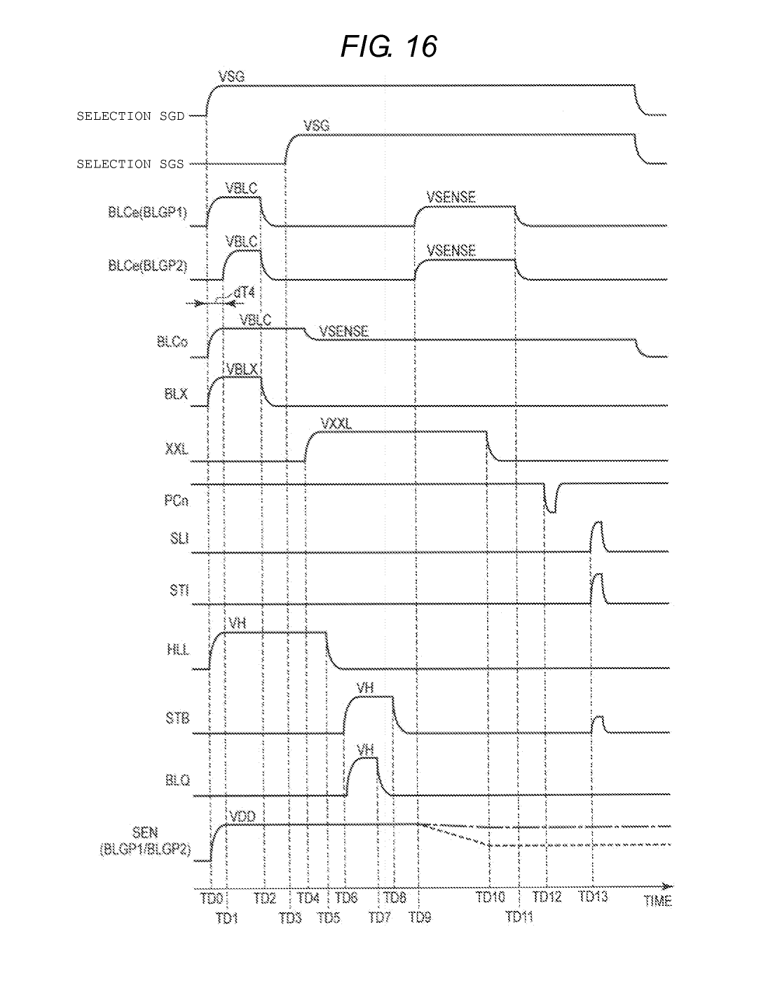

Next, with reference to FIG. 16, a description will be made of an operation of the sense module according to the fourth embodiment during reading data. The sequencer 111 of the present embodiment shifts a timing for precharging the first group bit line BLGP1 and a timing for precharging the second group bit line BLGP2. Hereinafter, a description will be made of an operation when an even-numbered bit line is selected, and an odd-numbered bit line is unselected. In the same manner as in the first embodiment, hereinafter, a description will be made of a case where a capacitance of the first group bit line BLGP1 is larger than a capacitance of the second group bit line BLGP2. In addition, each signal is given by, for example, the sequencer 111.

Time Point TD0 and Time Point TD1

As described in the second embodiment related to the time point TB1 and the time point TB2 of FIG. 10, the time required for the precharge is changed depending on a capacitance of the bit line. In the same manner as in the operation at the time point TB1 and the time point TB2 of FIG. 10 of the second embodiment, the sense module 141 according to the present embodiment precharges the first group bit line BLGP1 earlier than the second group bit line BLGP2.

More specifically, as illustrated in FIG. 16, at the time point TD0, the sequencer 111 sets the signal BLCe for the even-numbered bit line BLe of the first group bit line BLGP1 to an “H” level (voltage VBLC).

The sequencer 111 performs the same operation as the operation at the time point TC0 described in the third embodiment in relation to other signals.

As a result, the even-numbered bit line BLe of the first group bit line BLGP1 is precharged to a voltage (VBLC-Vt), and the voltage VSS is applied to the odd-numbered bit line BLo.

As illustrated in FIG. 16, at the time point TD1 after the time dT4 has elapsed from the time point TD0, the sequencer 111 sets the signal BLCe for the even-numbered bit line BLe of the second group bit line BLGP2 to an “H” level (voltage VBLC).

The time dT4 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the time dT4 is read to, for example, the register 113. The sequencer 111 refers to the register 113 in order to refer to the time dT4.

Time Point TD2 to Time Point TD8

The sequencer 111 performs the same operations as the operations at the time points TC1 to TC7 described in the third embodiment.

Time Point TD9

The sequencer 111 according to the present embodiment sets the signal BLCe of the sense module 141 connected to the even-numbered bit line BLe to an “H” level (VSENSE). Consequently, a sensing operation on the even-numbered bit line BLe is started.

Time Point TD10 to Time Point TD13

The sequencer 111 performs the same operations as the operations at the time points TC10 to TC13 described in the third embodiment.

### Operation and Effect According to Fourth Embodiment

According to the above-described embodiment, the sequencer changes a precharge timing during a sensing operation according to parasitic capacitance caused by a disposition of the semiconductor pillars SP. Consequently, the same operation and effect as in the second embodiment may be achieved.

### Fourth Modification Example

In the same manner as in the modification example of the first embodiment, the operation of the sense module of the fourth embodiment may also be applied to a case where there are three or more semiconductor pillar groups.

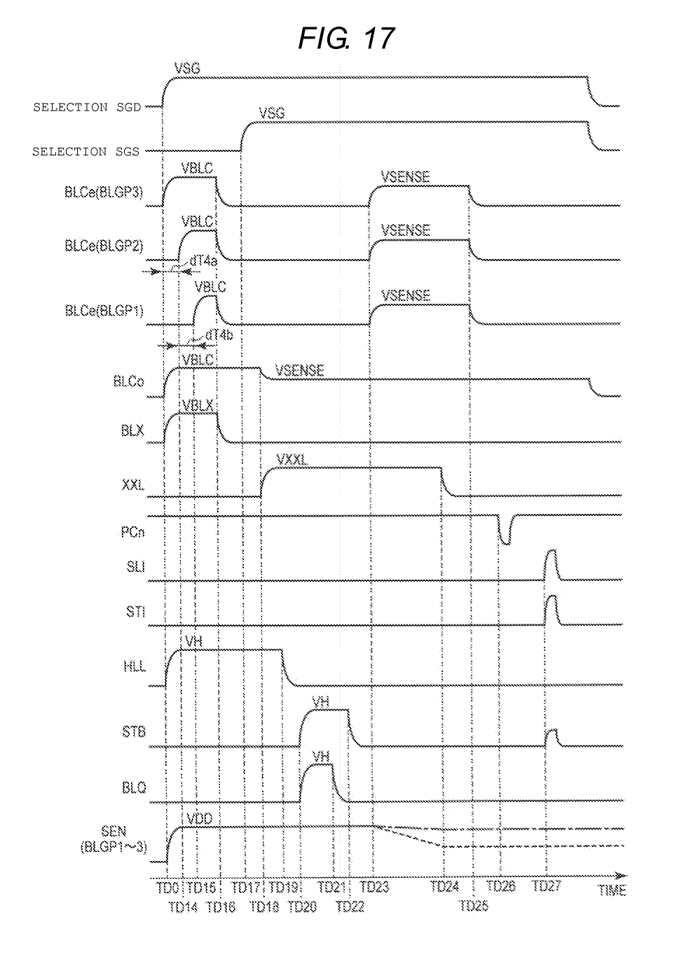

With reference to FIG. 17, a description will be made of a case where the configuration described in FIG. 8 is applied to an operation of the sense module of the fourth embodiment.

### Operation of Sense Module According to the Fourth Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TD0, Time Point TD14, and Time Point TD15

As described in a second modification example of the second embodiment, the time required for the precharge is changed depending on a capacitance of the bit line. Therefore, the sense module 141 according to the present modification example precharges the third group bit line BLGP3 earlier than the first group bit line BLGP1 and the second group bit line BLGP2. Further, the sense module 141 according to the present modification example precharges the second group bit line BLGP2 earlier than the first group bit line BLGP1.

More specifically, as illustrated in FIG. 17, at the time point TD0, the sequencer 111 sets the signal BLCe for the even-numbered bit line BLe of the third group bit line BLGP3 to an “H” level (voltage VBLC).

The sequencer 111 performs the same operation as the operation at the time point TC0 described in the third embodiment in relation to other signals.

As a result, the even-numbered bit line BLe of the third group bit line BLGP3 is precharged to a voltage (VBLC−Vt), and the voltage VSS is applied to the odd-numbered bit line BLo.

As illustrated in FIG. 17, at the time point TD14 after the time dT4a has elapsed from the time point TD0, the sequencer 111 sets the signal BLCe for the even-numbered bit line BLe of the second group bit line BLGP2 to an “H” level (voltage VBLC).

As illustrated in FIG. 17, at the time point TD15 after the time dT4b has elapsed from the time point TD14, the sequencer 111 sets the signal BLCe for the even-numbered bit line BLe of the first group bit line BLGP1 to an “H” level (voltage VBLC).

The time dT4a and the time dT4b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the time dT4a and the time dT4b are read to, for example, the register 113. The sequencer 111 refers to the register 113 in order to refer to the time dT4a and the time dT4b.

Time Point TD16 to Time Point TD27

The sequencer 111 performs the same operations as the operations at the time points TD2 to TD13 described in the fourth embodiment.

As mentioned above, a bit line is precharged in consideration of the capacitance of the bit line, and thus a variation between the time to complete precharge of the first group bit line BLGP1, the time to complete precharge of the second group bit line BLGP2, and the time to complete precharge of the third group bit line BLGP3 may be suppressed.

In the present modification example, semiconductor pillars are classified into three groups, and the sequencer 111 controls timings for performing precharge of the bit lines of the three groups. However, the present modification example is not limited thereto, and the semiconductor pillars may be classified into four or more groups. In addition, information regarding timings for precharging the bit lines of the four or more groups may be stored in the ROM fuse region (not illustrated) provided in the memory cell array 130. Consequently, the sequencer 111 may control timings for precharging the bit lines of the four or more groups.

### Fifth Embodiment

Next, a fifth embodiment will be described. In a semiconductor memory device according to the fifth embodiment, an operation of a sense module is different from the operation of the sense module according to the fourth embodiment. In addition, a fundamental configuration and a fundamental operation of the memory device according to the fifth embodiment are the same as those of the memory device according to the fourth embodiment. Therefore, description of the content described in the fourth embodiment and content which may be easily analogized from the fourth embodiment will be omitted.

### Operation of Sense Module According to Fifth Embodiment

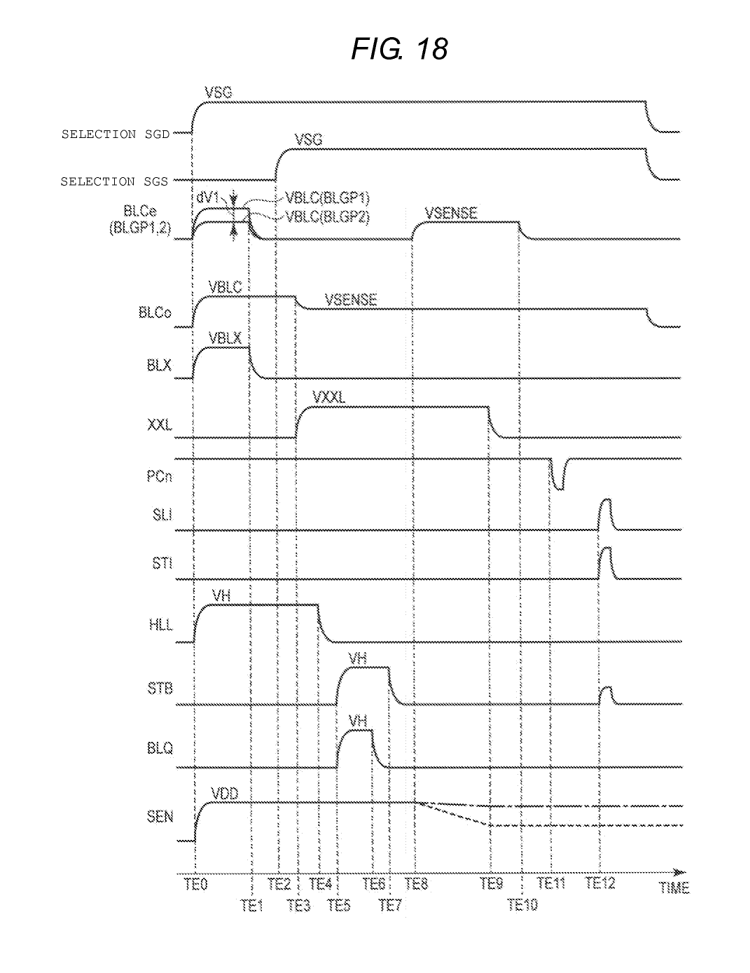

Next, with reference to FIG. 18, a description will be made of an operation of the sense module according to the fifth embodiment during reading data. The sequencer 111 of the present embodiment shifts a voltage for precharging the first group bit line BLGP1 and a voltage for precharging the second group bit line BLGP2. Hereinafter, a description will be made of an operation when an even-numbered bit line is selected, and an odd-numbered bit line is unselected. In the same manner as in the first embodiment, hereinafter, a description will be made of a case where a capacitance of the first group bit line BLGP1 is larger than a capacitance of the second group bit line BLGP2. In addition, each signal is given by, for example, the sequencer 111.

Time Point TE0

The sequencer 111 according to the fifth embodiment controls a voltage of the signal BLC in consideration of a difference between the capacitance of the first group bit line BLGP1 and the capacitance of the second group bit line BLGP2. Specifically, the sequencer 111 performs control so that a voltage which is a voltage dV1 higher than a voltage applied to the second group bit line BLGP2 is applied to the first group bit line BLGP1.

As illustrated in FIG. 18, the sequencer 111 sets the signal BLCe for the even-numbered bit line BLe of the second group bit line BLGP2 to a voltage VBLC(BLGP2). In addition, the sequencer 111 sets the signal BLCe for the even-numbered bit line BLe of the first group bit line BLGP1 to a voltage VBLC(BLGP1) (=VBLC(BLGP2)+dV1).

The sequencer 111 performs the same operation as the operation at the time point TC0 described in the third embodiment in relation to other signals.

As a result, the even-numbered bit line BLe of the first group bit line BLGP1 is precharged to a voltage (VBLC(BLGP1)−Vt). The even-numbered bit line BLe of the second group bit line BLGP2 is precharged to a voltage (VBLC(BLGP2)−Vt). In addition, the voltage VSS is applied to the odd-numbered bit line BLo.

The voltage dV1 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the voltage dV1 is read to, for example, the register 113. The sequencer 111 refers to the register 113 in order to refer to the voltage dV1.

Time Point TE1 to Time Point TE12

The sequencer 111 performs the same operations as the operations at the time points TD2 to TD13 described in the fourth embodiment.

### Operations and Effects According to Fifth Embodiment

According to the above-described embodiment, the sequencer changes voltages which are input to the gate of the clamping transistor during a sensing operation according to parasitic capacitance caused by a disposition of the semiconductor pillars SP. Consequently, an appropriate voltage may be applied to a bit line connected to the semiconductor pillar SP with the great capacitance. Therefore, a variation in a sensing result caused by a capacitance variation of the semiconductor pillar SP may be suppressed. As a result, even if there is a capacitance variation of the semiconductor pillar SP, a sensing operation may be performed with high accuracy.

### Fifth Modification Example

In the same manner as in the modification example of the first embodiment, the operation of the sense module of the fifth embodiment may also be applied to a case where there are three or more semiconductor pillar groups.

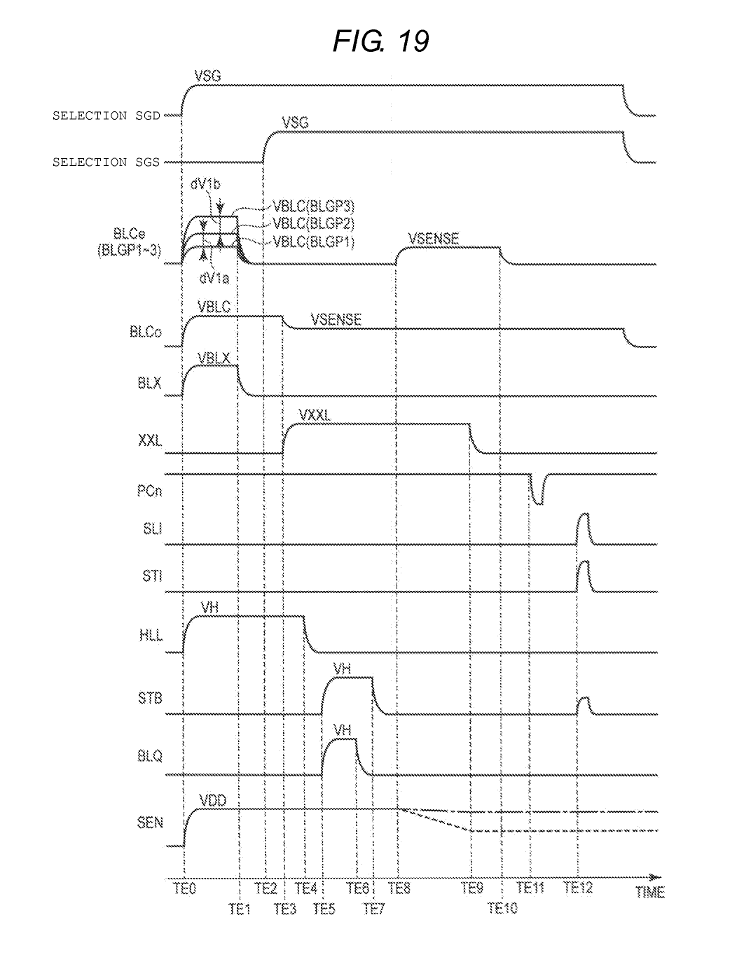

With reference to FIG. 19, a description will be made of a case where the configuration described in FIG. 8 is applied to an operation of the sense module of the fifth embodiment.

### Operation of Sense Module According to the Fifth Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TE0

The sequencer 111 according to the present modification example controls a voltage of the signal BLC in consideration of a difference between the capacitance of the first group bit line BLGP1, the capacitance of the second group bit line BLGP2, and the capacitance of the third group bit line BLGP3. Specifically, the sequencer 111 performs control so that a voltage which is a voltage dV1a higher than a voltage applied to the first group bit line BLGP1 is applied to the second group bit line BLGP2. In addition, the sequencer 111 performs control so that a voltage which is a voltage dV1b higher than a voltage applied to the second group bit line BLGP2 is applied to the third group bit line BLGP3.

As illustrated in FIG. 19, the sequencer 111 sets the signal BLCe for the even-numbered bit line BLe of the first group bit line BLGP1 to a voltage VBLC(BLGP1). In addition, the sequencer 111 sets the signal BLCe for the even-numbered bit line BLe of the second group bit line BLGP2 to a voltage VBLC(BLGP2) (=VBLC(BLGP1)+dV1a). Further, the sequencer 111 sets the signal BLCe for the even-numbered bit line BLe of the third group bit line BLGP3 to a voltage VBLC(BLGP3) (=VBLC(BLGP2)+dV1b).

The sequencer 111 performs the same operation as the operation at the time point TC0 described in the third embodiment in relation to other signals.

As a result, the even-numbered bit line BLe of the first group bit line BLGP1 is precharged to a voltage (VBLC(BLGP1)−Vt). The even-numbered bit line BLe of the second group bit line BLGP2 is precharged to a voltage (VBLC(BLGP2)−Vt). In addition, the even-numbered bit line BLe of the third group bit line BLGP3 is precharged to a voltage (VBLC(BLGP3)−Vt). Further, the voltage VSS is applied to the odd-numbered bit line BLo.

The voltage dV1a and the voltage dV1b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the voltage dV1a and the voltage dV1b are read to, for example, the register 113. The sequencer 111 refers to the register 113 in order to refer to the voltage dV1a and the voltage dV1b.

Time Point TE1 to Time Point TE12

The sequencer 111 performs the same operations as the operations at the time points TD2 to TD13 described in the fourth embodiment.

As mentioned above, a bit line is precharged in consideration of the capacitance of the bit line, and thus the first group bit line BLGP1, the second group bit line BLGP2, and the third group bit line BLGP3 may be precharged with high accuracy.

In the present modification example, semiconductor pillars are classified into three groups, and the sequencer 111 controls voltages for performing precharge of the bit lines of the three groups are controlled. However, the present modification example is not limited thereto, and the semiconductor pillars may be classified into four or more groups. In addition, information regarding voltages for precharging the bit lines of the four or more groups may be stored in the ROM fuse region (not illustrated) provided in the memory cell array 130. Consequently, the sequencer 111 may control voltages for precharging the bit lines of the four or more groups.

### Sixth Embodiment

Next, a sixth embodiment will be described. In a semiconductor memory device according to the sixth embodiment, a sense circuit is different from the sense circuit according to the third embodiment. In addition, a fundamental configuration and a fundamental operation of the memory device according to the sixth embodiment are the same as those of the memory device according to the third embodiment. Therefore, description of the content described in the third embodiment and content which may be easily analogized from the third embodiment will be omitted.

### Sense Module According to Sixth Embodiment

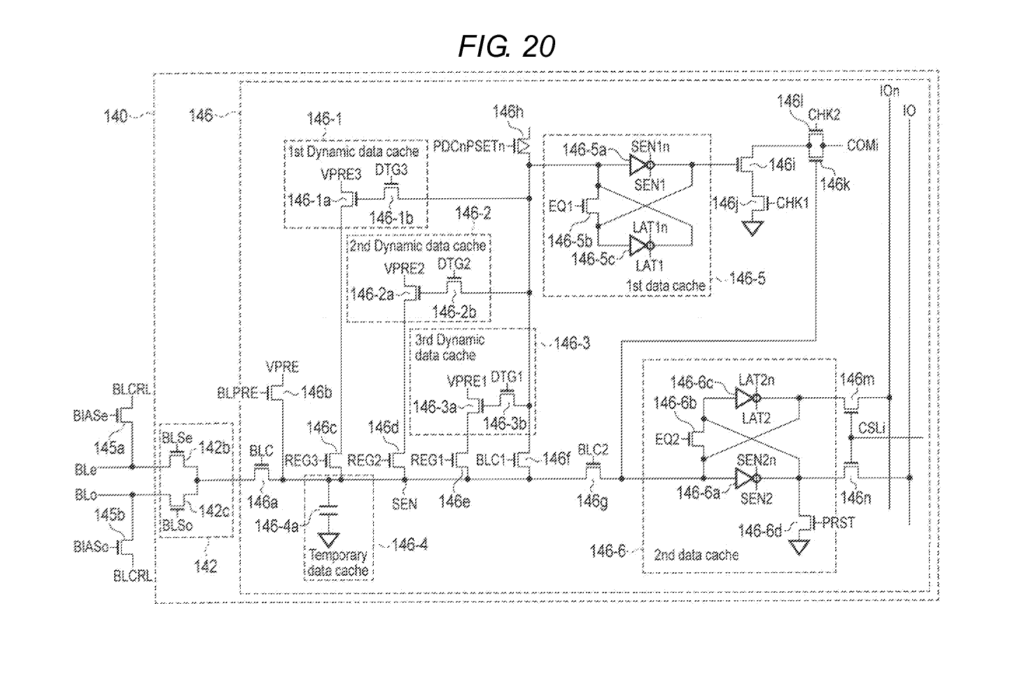

With reference to FIG. 20, a sense module 141 according to the present embodiment will be described. The sense module 141 according to the present embodiment includes a hookup portion 142 and a sense amplifier/data latch 146. The sense amplifier/data latch 146 of the present embodiment corresponds to the sense amplifier 143 and the data latch 144 illustrated in FIG. 12.

As illustrated in FIG. 20, the sense module 141 includes three dynamic data caches 146-1 to 146-3, a temporary data cache 146-4, a first data cache 146-5, and a second data cache 146-6. The dynamic data caches 146-1 to 146-3 and the temporary data cache 146-4 may be provided as necessary. In addition, the dynamic data caches 146-1 to 146-3 may be used as a cache which holds data for writing an intermediate potential (VQPW) between VDD (high potential) and VSS (low potential) to a bit line during programming.

The first data cache 146-5 includes clocked inverters 146-5a and 146-5c, and an nMOS transistor 146-5b. The second data cache 146-6 includes clocked inverters 146-6a and 146-6b, and an nMOS transistors 146-6b and 146-6d. The first dynamic data cache 146-1 includes nMOS transistors 146-1a and 146-1b. The second dynamic data cache 146-2 includes nMOS transistors 146-2a and 146-2b. The third dynamic data cache 146-3 includes nMOS transistors 146-3a and 146-3b. The temporary data cache 146-4 includes a capacitor 146-4a. Further, circuit configurations of the first dynamic data cache 146-1, the second dynamic data cache 146-2, the third dynamic data cache 146-3, the temporary data cache 146-4, the first data cache 146-5, and the second data cache 146-6 are not limited to configurations illustrated in FIG. 20, and other circuit configurations may be employed.

The sense amplifier/data latch 146 is connected to a corresponding even-numbered bit line BLe or odd-numbered bit line BLo via the hookup portion 142. Signals BLSe and BLSo are respectively input to gates of transistors 142b and 142c. In addition, the even-numbered bit line BLe and the odd-numbered bit line BLo are respectively connected to sources of nMOS transistors 145a and 145b. The transistors 145a and 145b include gates to which signals BIASe and BIASo are input, and drains to which a signal BLCRL is input.

### Operation of Sense Module According to Sixth Embodiment

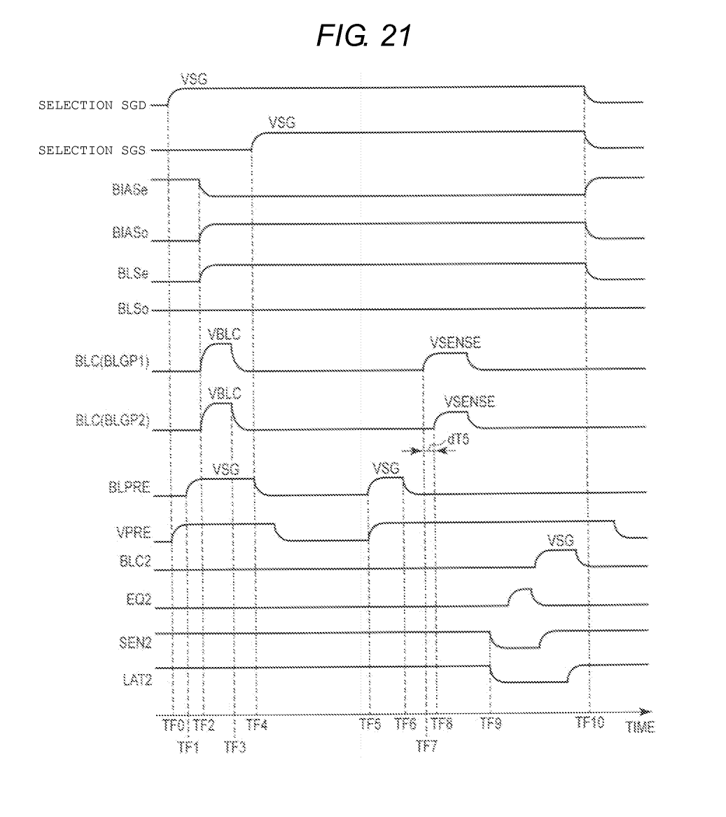

Next, with reference to FIG. 21, a description will be made of an operation of the sense module according to the sixth embodiment during reading data. The sequencer 111 of the present embodiment shifts a timing for performing a sensing operation of the first group bit line BLGP1 and a timing for performing a sensing operation of the second group bit line BLGP2. Hereinafter, a description will be made of an operation when an even-numbered bit line is selected, and an odd-numbered bit line is unselected. In the same manner as in the first embodiment, hereinafter, a description will be made of a case where a capacitance of the first group bit line BLGP1 is larger than a capacitance of the second group bit line BLGP2. In addition, each signal is given by, for example, the sequencer 111.

Time Point TF0

As illustrated in FIG. 21, first, the selection gate line (SGD) of a selected string unit of a selected block is set to an “H” level. In addition, in the sense module 141, a precharge power supply potential VPRE is set to a voltage VDD. 0 V or a non-selection voltage VBB (for example, a negative voltage) is applied to the selection gate line SGD of an unselected string unit.

Time Point TF1

The sense module 141 precharges a bit line (in this example, the even-numbered bit line BLe) which is a reading target in advance. Specifically, the sequencer 111 sets a signal BLPRE to an “H” level so as to turn on the transistor 146b, and thus the temporary data cache 146-4 is precharged to the voltage VDD.

Time Point TF2

The sequencer 111 performs setting of bit line selection signals BLSe and BLSo, and bias selection signals BIASe and BIASo. In this example, the even-numbered bit line BLe is selected, and thus the sequencer 111 sets the even-numbered bit line selection signal BLSe to an “H” level. In addition, the sequencer 111 sets the signal BIASo to an “H” level in order to fix the odd-numbered bit line BLo to the voltage BLCRL (=VSS).

In addition, the signal BLC is set to a clamping voltage VBLC for precharging a bit line, and thus the even-numbered bit line BLe is precharged to a predetermined voltage.

In the above-described manner, the even-numbered bit line BLe is charged to 0.7 V, and the odd-numbered bit line BLo is fixed to the voltage VSS.

Time Point TF3

Next, the sequencer 111 sets the signal BLC to 0 V, so that the even-numbered bit line BLe enters an electrical floating state.

Time Point TF4

Next, the sequencer 111 applies a voltage Vsg to the source side selection gate line SGS of the selected string unit to a voltage Vsg. 0 V or the non-selection voltage VBB (for example, a negative voltage) is applied to other selection gate lines SGS of the unselected string unit. Consequently, if a threshold value of the memory cell is higher than a verification level, the bit line is not discharged, and if the threshold value is lower than the verification level, a reading current flows through the bit line which is thus discharged.

Time Point TF5 to Time Point TF6

Next, from the time point TF5 to the time point TF6, the sequencer 111 sets the signal VPRE to the voltage VDD, and sets the signal BLPRE to the voltage Vsg. Consequently, the temporary data cache 146-4 is precharged to the voltage VDD.

Time Point TF7 to Time Point TF8

The capacitance of the first group bit line BLGP1 is larger than the capacitance of the second group bit line BLGP2. For this reason, the time required for a sensing operation of the first group bit line BLGP1 is longer than the time required for a sensing operation of the second group bit line BLGP2.

Therefore, at the time point TF7, the sequencer 111 according to the present embodiment sets the signal BLC of the sense module 141 connected to the first group bit line BLGP1 to an “H” level (VSENSE) earlier than the second group bit line BLGP2. Consequently, the sequencer 111 starts a sensing operation on the first group bit line BLGP1 earlier than that on the second group bit line BLGP2. If a selected memory cell is turned on, and thus the even-numbered bit line BLe of the first group bit line BLGP1 is discharged, a potential of the node SEN is also reduced. On the other hand, if the selected memory cell is turned off, the even-numbered bit line BLe of the first group bit line BLGP1 is maintained substantially to have the precharge voltage, and thus the potential of the node SEN is not changed much.

Subsequently, at the time point TF8 after the time dT5 has elapsed from the time point TF7, the sequencer 111 according to the present embodiment sets the signal BLC of the sense module 141 connected to the second group bit line BLGP2 to an “H” level (VSENSE). Consequently, a sensing operation on the second group bit line BLGP2 is started.

The time dT5 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the time dT5 is read to, for example, the register 113. The sequencer 111 refers to the register 113 in order to refer to the time dT5.

Time Point TF9

Next, the sensed data is received by the second data cache 146-6. Specifically, the sequencer 111 sets signals SEN2 and LAT2 to an “L” level, so that a signal EQ2 is set to the voltage VDD, and thus the node SEN1 and the node N2 have the same potential. Then, the sequencer 111 sets a signal BLC2 to “VDD+Vth”, and thus the data in the temporary data cache 146-4 is transmitted to the second data cache 146-6. As a result, if the node SEN is in an “H” level, the data in the second data cache 146-6 becomes “1”. In addition, if the node SEN is in an “L” level (for example, 0.4 V), the data in the second data cache 146-6 becomes “0”. As mentioned above, data is read from the even-numbered bit line BLe.

Time Point TF10

Then, the sequencer 111 resets the respective nodes and signals.

Reading of the odd-numbered bit line BLo is also performed as mentioned above. In this case, the sequencer 111 sets the signal BLSo to an “H” level, and sets the signal BLSe to an “L” level. In addition, the sequencer 111 sets the signal BIASe to an “H” level, and sets the signal BIASo to an “L” level.

### Operation and Effect According to Sixth Embodiment

According to the above-described embodiment, an operation of the sense circuit is controlled according to parasitic capacitance caused by a disposition of the semiconductor pillars SP. Consequently, the same effect as in the first embodiment may be achieved.

### Sixth Modification Example

In the same manner as in the modification example of the first embodiment, the operation of the sense module of the sixth embodiment may also be applied to a case where there are three or more semiconductor pillar groups.

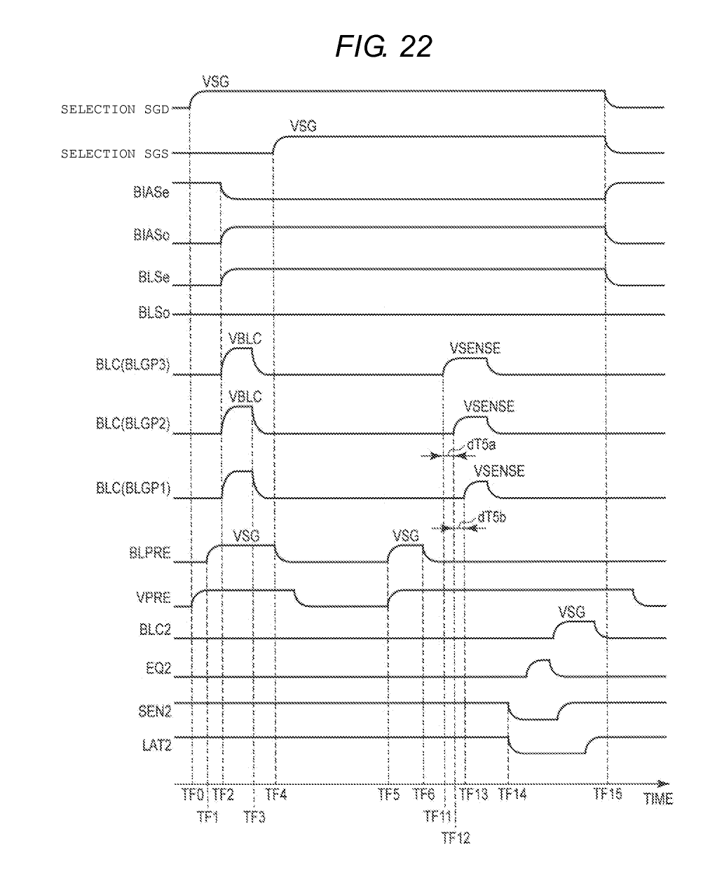

With reference to FIG. 22, a description will be made of a case where the configuration described in FIG. 8 is applied to an operation of the sense module of the sixth embodiment.

### Operation of Sense Module According to the Sixth Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TF0 to Time Point TF6

The sequencer 111 performs the same operations as the operations at the time points TF0 to TF6 described in the sixth embodiment.

Time Point TF11, Time Point TF12, and Time Point TF13

The time required for a sensing operation of the third group bit line BLGP3 is longer than the time required for a sensing operation of the second group bit line BLGP2. In addition, the time required for a sensing operation of the second group bit line BLGP2 is longer than the time required for a sensing operation of the first group bit line BLGP1.

Therefore, at the time point TF11, the sequencer 111 according to the present modification example sets the signal BLC of the sense module 141 connected to the third group bit line BLGP3 to an “H” level (VSENSE) earlier than the first group bit line BLGP1 and the second group bit line BLGP2. Consequently, the sequencer 111 starts a sensing operation on the third group bit line BLGP3 earlier than that on the first group bit line BLGP1 and the second group bit line BLGP2.

Subsequently, at the time point TF12 after the time dT5a has elapsed from the time point TF11, the sequencer 111 according to the present modification example sets the signal BLC of the sense module 141 connected to the second group bit line BLGP2 to an “H” level (VSENSE). Consequently, a sensing operation on the second group bit line BLGP2 is started.

In addition, at the time point TF13 after the time dT5b has elapsed from the time point TF12, the sequencer 111 according to the present modification example sets the signal BLC of the sense module 141 connected to the first group bit line BLGP1 to an “H” level (VSENSE). Consequently, a sensing operation on the first group bit line BLGP1 is started.

The time dT5a and the time dT5b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the time dT5a and the time dT5b are read to, for example, the register 113. The sequencer 111 refers to the register 113 in order to refer to the time dT5a and the time dT5b.

Time Point TD14 and Time Point TD15

The sequencer 111 performs the same operations as the operations at the time point TF9 and the time point TF10 described in the sixth embodiment.

As mentioned above, a bit line is precharged in consideration of the capacitance of the bit line, and thus the first group bit line BLGP1, the second group bit line BLGP2, and the third group bit line BLGP3 may be precharged with high accuracy.

In the present modification example, semiconductor pillars are classified into three groups, and the sequencer 111 controls voltages for performing precharge of the bit lines of the three groups are controlled. However, the present modification example is not limited thereto, and the semiconductor pillars may be classified into four or more groups. In addition, information regarding voltages for precharging the bit lines of the four or more groups may be stored in the ROM fuse region (not illustrated) provided in the memory cell array 130. Consequently, the sequencer 111 may control voltages for precharging the bit lines of the four or more groups.

### Seventh Embodiment

Next, a seventh embodiment will be described. In a semiconductor memory device according to the seventh embodiment, an operation of a sense module is different from the operation of the sense module according to the sixth embodiment. In addition, a fundamental configuration and a fundamental operation of the memory device according to the seventh embodiment are the same as those of the memory device according to the sixth embodiment. Therefore, description of the content described in the sixth embodiment and content which may be easily analogized from the sixth embodiment will be omitted.

### Operation of Sense Module According to Seventh Embodiment

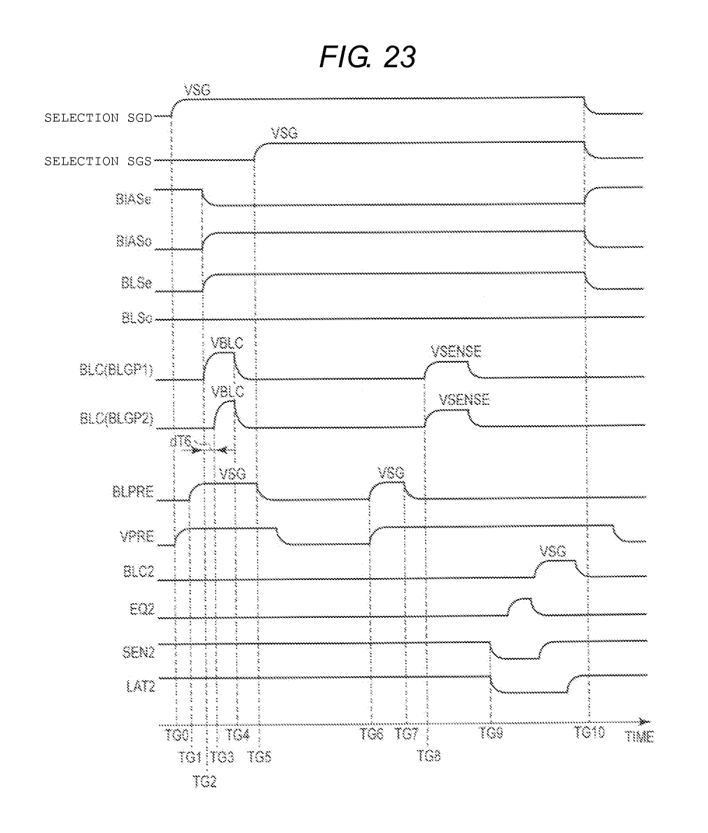

Next, with reference to FIG. 23, a description will be made of an operation of the sense module according to the seventh embodiment during reading data. The sequencer 111 of the present embodiment shifts a timing for precharging the first group bit line BLGP1 and a timing for precharging the second group bit line BLGP2. Hereinafter, a description will be made of an operation when an even-numbered bit line is selected, and an odd-numbered bit line is unselected. In the same manner as in the first embodiment, hereinafter, a description will be made of a case where a capacitance of the first group bit line BLGP1 is larger than a capacitance of the second group bit line BLGP2. In addition, each signal is given by, for example, the sequencer 111.

Time Point TG0 and Time Point TG1

The sequencer 111 performs the same operations as the operations at the time points TF0 and the time point TF1 described in the sixth embodiment.

Time Point TG2 and Time Point TG3

The time required for the precharge is changed depending on a capacitance of the bit line. Therefore, the sense module 141 according to the present embodiment precharges the first group bit line BLGP1 earlier than the second group bit line BLGP2.

Specifically, at the time point TG2, the sense module 141 precharges the first group bit line BLGP1 (in this example, the even-numbered bit line BLe) which is a reading target in advance. The sequencer 111 performs setting of bit line selection signals BLSe and BLSo, and bias selection signals BIASe and BIASo. In this example, the even-numbered bit line BLe is selected, and thus the sequencer 111 sets the even-numbered bit line selection signal BLSe to an “H” level. In addition, the sequencer 111 sets the signal BIASo to an “H” level in order to fix the odd-numbered bit line BLo to the voltage BLCRL (=VSS).

In addition, the sequencer 111 sets the signal BLC of the sense module 141 connected to the first group bit line BLGP1 to a clamping voltage VBLC for precharging a bit line. Thus, the even-numbered bit line BLe of the first group bit line BLGP1 is precharged to a predetermined voltage.

In the above-described manner, the even-numbered bit line BLe of the first group bit line BLGP1 is charged, and the odd-numbered bit line BLo is fixed to the voltage VSS.

Subsequently, at the time point TG3 after the time dT6 has elapsed from the time point TG2, the sequencer 111 sets the signal BLC of the sense module 141 connected to the second group bit line BLGP2 to the clamping voltage VBLC for precharging a bit line. Thus, the even-numbered bit line BLe of the second group bit line BLGP2 is precharged to a predetermined voltage.

As mentioned above, the even-numbered bit line BLe of the second group bit line BLGP2 is charged.

The time dT6 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the time dT6 is read to, for example, the register 113. The sequencer 111 refers to the register 113 in order to refer to the time dT6.

As mentioned above, the precharge is performed in consideration of the capacitance of the bit line, and thus a variation between the time at which precharge of the first group bit line BLGP1 is completed and the time at which precharge of the second group bit line BLGP2 is completed may be suppressed.

Time Point TG4 to Time Point TG7

The sequencer 111 performs the same operations as the operations at the time point TF3 to the time point TF6 described in the sixth embodiment.

Time Point TG8

The sequencer 111 according to the present embodiment sets the signal BLC of the sense module 141 to an “H” level (VSENSE). Consequently, the sequencer 111 starts a sensing operation on the even-numbered bit line BLe.

Time Point TG9 and Time Point TG10

The sequencer 111 performs the same operations as the operations at the time point TF9 and the time point TF10 described in the sixth embodiment.

### Operation and Effect According to Seventh Embodiment

According to the above-described embodiment, in the same manner as in the second embodiment, an operation of the sense module is controlled according to parasitic capacitance caused by a disposition of the semiconductor pillars SP. Consequently, the same effect as in the second embodiment may be achieved.

### Seventh Modification Example

In the same manner as in the modification example of the first embodiment, the operation of the sense module of the seventh embodiment may also be applied to a case where there are three or more semiconductor pillar groups.

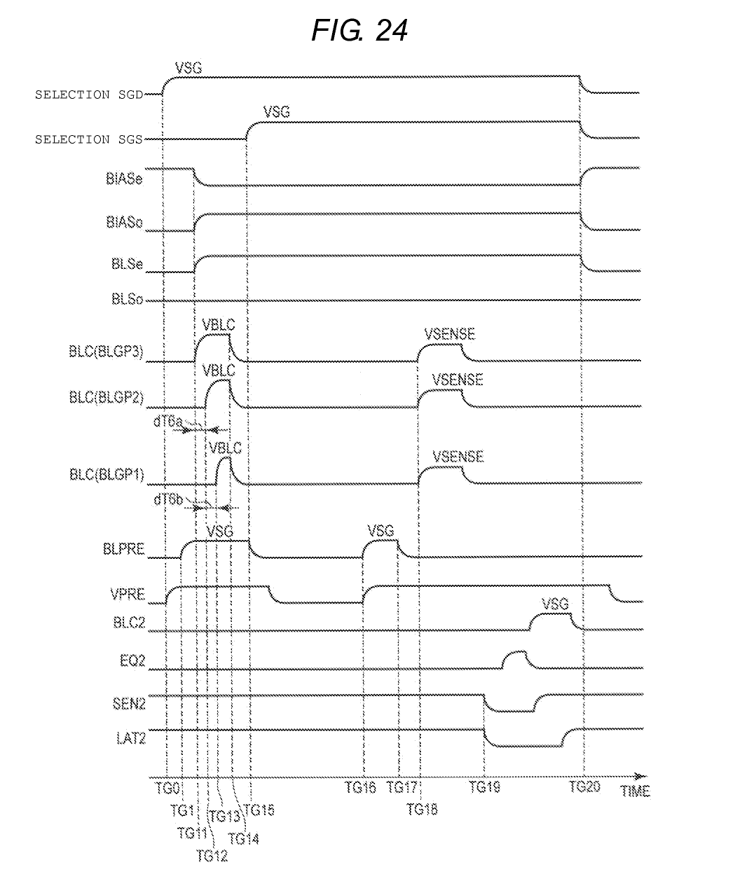

With reference to FIG. 24, a description will be made of a case where the configuration described in FIG. 8 is applied to an operation of the sense module of the seventh embodiment.

### Operation of Sense Module According to the Seventh Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TG0 and Time Point TG1

The sequencer 111 performs the same operations as the operations at the time points TF0 and time point TF1 described in the sixth embodiment.

Time Point TG11, Time Point TG12, and Time Point TG13

The time required for the precharge is changed depending on a capacitance of the bit line. Therefore, the sense module 141 according to the present modification example precharges the third group bit line BLGP3 earlier than the first group bit line BLGP1 and the second group bit line BLGP2. Further, the sense module 141 according to the present modification example precharges the second group bit line BLGP2 earlier than the first group bit line BLGP1.

Specifically, at the time point TG11, the sense module 141 precharges the third group bit line BLGP3 (in this example, the even-numbered bit line BLe) which is a reading target in advance. The sequencer 111 performs setting of bit line selection signals BLSe and BLSo, and bias selection signals BIASe and BIASo. In this example, the even-numbered bit line BLe is selected, and thus the sequencer 111 sets the even-numbered bit line selection signal BLSe to an “H” level. In addition, the sequencer 111 sets the signal BIASo to an “H” level in order to fix the odd-numbered bit line BLo to the voltage BLCRL (=VSS).

In addition, the sequencer 111 sets the signal BLC of the sense module 141 connected to the third group bit line BLGP3 to a clamping voltage VBLC for precharging a bit line. Thus, the even-numbered bit line BLe of the third group bit line BLGP3 is precharged to a predetermined voltage.

In the above-described manner, the even-numbered bit line BLe of the third group bit line BLGP3 is charged, and the odd-numbered bit line BLo is fixed to the voltage VSS.

Subsequently, at the time point TG12 after the time dT6a has elapsed from the time point TG11, the sequencer 111 sets the signal BLC of the sense module 141 connected to the second group bit line BLGP2 to the clamping voltage VBLC for precharging a bit line. Thus, the even-numbered bit line BLe of the second group bit line BLGP2 is precharged to a predetermined voltage. Consequently, the even-numbered bit line BLe of the second group bit line BLGP2 is charged.

In addition, at the time point TG13 after the time dT6b has elapsed from the time point TG12, the sequencer 111 sets the signal BLC of the sense module 141 connected to the first group bit line BLGP1 to the clamping voltage VBLC for precharging a bit line. Thus, the even-numbered bit line BLe of the first group bit line BLGP1 is precharged to a predetermined voltage. Consequently, the even-numbered bit line BLe of the first group bit line BLGP1 is charged.

The time dT6a and the time dT6b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the time dT6a and the time dT6b are read to, for example, the register 113. The sequencer 111 refers to the register 113 in order to refer to the time dT6a and the time dT6b.

Time Point TG14 to Time Point TG20

The sequencer 111 performs the same operations as the operations at the time point TG4 to the time point TG10 described in the seventh embodiment.

As mentioned above, a bit line is precharged in consideration of the capacitance of the bit line, and thus variations between precharge end timings of the first group bit line BLGP1, the second group bit line BLGP2, and the third group bit line BLGP3 may be suppressed.

In the present modification example, semiconductor pillars are classified into three groups, and the sequencer 111 controls timings for performing precharge of the bit lines of the three groups are controlled. However, the present modification example is not limited thereto, and the semiconductor pillars may be classified into four or more groups. In addition, information regarding timings for precharging the bit lines of the four or more groups may be stored in the ROM fuse region (not illustrated) provided in the memory cell array 130. Consequently, the sequencer 111 may control timings for precharging the bit lines of the four or more groups.

### Eighth Embodiment

Next, an eighth embodiment will be described. In a semiconductor memory device according to the eighth embodiment, an operation of a sense module is different from the operation of the sense module according to the sixth embodiment. In addition, a fundamental configuration and a fundamental operation of the memory device according to the eighth embodiment are the same as those of the memory device according to the sixth embodiment. Therefore, description of the content described in the sixth embodiment and content which may be easily analogized from the sixth embodiment will be omitted.

### Operation of Sense Module According to Eighth Embodiment

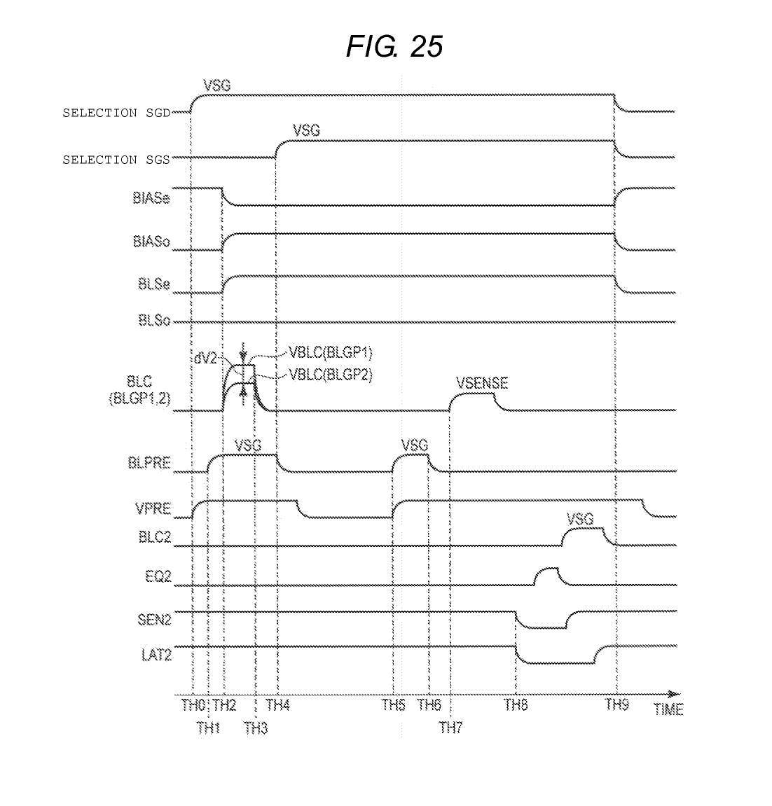

Next, with reference to FIG. 25, a description will be made of an operation of the sense module according to the eighth embodiment during reading data. Hereinafter, a description will be made of an operation when an even-numbered bit line is selected, and an odd-numbered bit line is unselected. In the same manner as in the first embodiment, hereinafter, a description will be made of a case where a capacitance of the first group bit line BLGP1 is larger than a capacitance of the second group bit line BLGP2. The sequencer 111 according to this exemplary embodiment makes a voltage for precharging the first group bit line BLGP1 higher than a voltage for precharging the second group bit line BLGP2. In addition, each signal is given by, for example, the sequencer 111.

Time Point TH0 and Time Point TH1

The sequencer 111 performs the same operations as the operations at the time points TG0 and the time point TG1 described in the seventh embodiment.

Time Point TH2

The sequencer 111 according to the eighth embodiment controls a voltage of the signal BLC in consideration of a difference between the capacitance of the first group bit line BLGP1 and the capacitance of the second group bit line BLGP2. Specifically, the sequencer 111 performs control so that a voltage which is a voltage dV2 higher than a voltage applied to the second group bit line BLGP2 is applied to the first group bit line BLGP1.

The sense module 141 precharges a bit line (in this example, the even-numbered bit line BLe) which is a reading target in advance. The sequencer 111 performs setting of bit line selection signals BLSe and BLSo, and bias selection signals BIASe and BIASo. In this example, the even-numbered bit line BLe is selected, and thus the sequencer 111 sets the even-numbered bit line selection signal BLSe to an “H” level. In addition, the sequencer 111 sets the signal BIASo to an “H” level in order to fix the odd-numbered bit line BLo to the voltage BLCRL (=VSS).

As illustrated in FIG. 25, the sequencer 111 sets the signal BLC for the second group bit line BLGP2 to a voltage VBLC(BLGP2). In addition, the sequencer 111 sets the signal BLC for the first group bit line BLGP1 to a voltage VBLC (BLGP1) (=VBLC(BLGP2)+dV2). Consequently, the even-numbered bit line BLe is precharged to a predetermined voltage.

In the above-described manner, the even-numbered bit line BLe is charged, and the odd-numbered bit line BLo is fixed to the voltage VSS.

The voltage dV2 is appropriately set in consideration of the capacitance of the first group bit line BLGP1 and the capacitance of the second group bit line BLGP2, and is stored in a ROM fuse region (not illustrated) or the like provided in the memory cell array 130. In addition, during starting the memory system 1, the voltage dV2 is read to, for example, the register 113. The sequencer 111 refers to the register 113 in order to refer to the voltage dV2.

Time Point TH3 to Time Point TH9

The sequencer 111 performs the same operations as the operations at the time points TG4 to TG10 described in the seventh embodiment.

### Operation and Effect According to Eighth Embodiment

According to the above-described embodiment, in the same manner as in the fifth embodiment, an operation of the sense circuit is controlled according to parasitic capacitance caused by a disposition of the semiconductor pillars SP. Consequently, the same effect as in the fifth embodiment may be achieved.

### Eighth Modification Example

In the same manner as in the modification example of the first embodiment, the operation of the sense module of the eighth embodiment during reading of data may also be applied to a case where there are three or more semiconductor pillar groups.

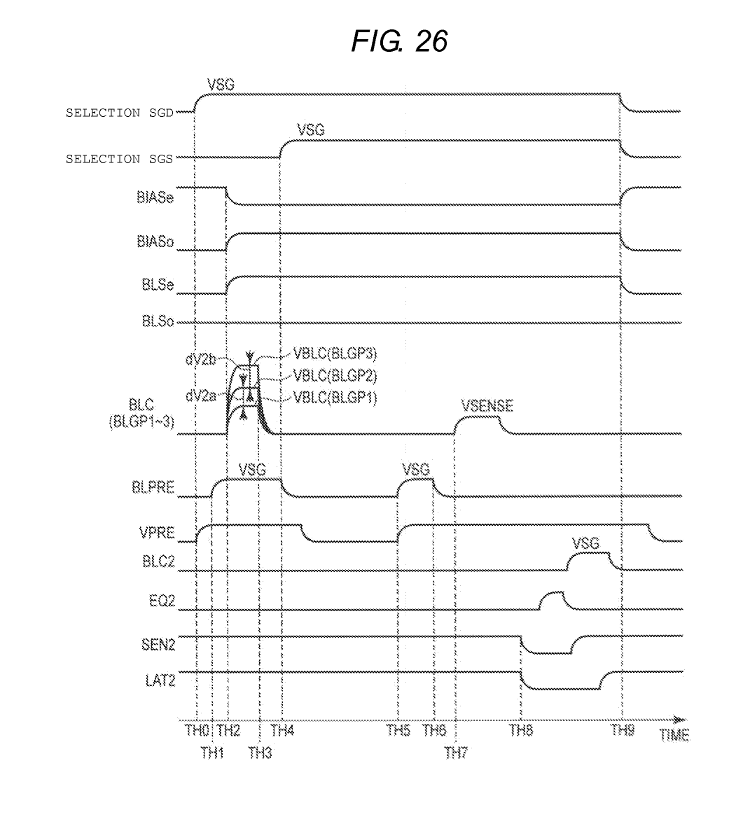

With reference to FIG. 26, a description will be made of a case where the configuration described in FIG. 8 is applied to an operation of the sense module of the eighth modification example.

### Operation of Sense Module According to the Eighth Modification Example

Hereinafter, a description will be made of a case where the capacitance of the third group bit line BLGP3 is larger than the capacitance of the second group bit line BLGP2, and the capacitance of the second group bit line BLGP2 is larger than the capacitance of the first group bit line BLGP1.

Time Point TH0 and Time Point TH1

The sequencer 111 performs the same operations as the operations at the time points TG0 and the time point TG1 described in the seventh embodiment.

Time Point TH2

The sequencer 111 according to the present modification example controls a voltage of the signal BLC in consideration of a difference between the capacitance of the first group bit line BLGP1, the capacitance of the second group bit line BLGP2, and the capacitance of the third group bit line BLGP3. Specifically, the sequencer 111 performs control so that a voltage which is a voltage dV2a higher than a voltage applied to the first group bit line BLGP1 is applied to the second group bit line BLGP2. In addition, the sequencer 111 performs control so that a voltage which is a voltage dV2b higher than a voltage applied to the second group bit line BLGP2 is applied to the third group bit line BLGP3.

As illustrated in FIG. 26, the sequencer 111 sets the signal BLC for the first group bit line BLGP1 to a voltage VBLC(BLGP1). In addition, the sequencer 111 sets the signal BLC for the second group bit line BLGP2 to a voltage VBLC(BLGP2) (=VBLC(BLGP1)+dV2a). Further, the sequencer 111 sets the signal BLC for the third group bit line BLGP3 to a voltage VBLC(BLGP3) (=VBLC(BLGP2)+dV2b). Consequently, the even-numbered bit line BLe is precharged to a predetermined voltage.

In the above-described manner, the even-numbered bit line BLe is charged, and the odd-numbered bit line BLo is fixed to the voltage VSS.

The voltage dV2a and the voltage dV2b are appropriately set in consideration of the capacitance of the first group bit line BLGP1, the capacitance of the second group bit line BLGP2, and the capacitance of the third group bit line BLGP3, and are stored in a ROM fuse region (not illustrated) or the like provided in the memory cell array 130. In addition, during starting the memory system 1, the voltage dV2a and the voltage dV2b are read to, for example, the register 113. The sequencer 111 refers to the register 113 in order to refer to the voltage dV2a and the voltage dV2b.

Time Point TH3 to Time Point TH9

The sequencer 111 performs the same operations as the operations at the time points TG4 to TG10 described in the seventh embodiment.

As mentioned above, a bit line is precharged in consideration of the capacitance of the bit line, and thus the first group bit line BLGP1, the second group bit line BLGP2, and the third group bit line BLGP3 may be precharged with high accuracy.

In the present modification example, semiconductor pillars are classified into three groups, and the sequencer 111 controls voltages for performing precharge of the bit lines of the three groups are controlled. However, the present modification example is not limited thereto, and the semiconductor pillars may be classified into four or more groups. In addition, information regarding voltages for precharging the bit lines of the four or more groups may be stored in the ROM fuse region (not illustrated) provided in the memory cell array 130. Consequently, the sequencer 111 may control voltages for precharging the bit lines of the four or more groups.

### Ninth Embodiment

Next, a ninth embodiment will be described. In the present embodiment, the sense circuit 140 and the sensing operation according to the first to eighth embodiments are applied to a semiconductor memory device which includes a memory cell array having a configuration different from that in the first to eighth embodiments. In addition, a fundamental configuration and a fundamental operation of the memory device according to the ninth are the same as those of the memory device according to the first to eighth embodiments. Therefore, description of the content described in the first to eighth embodiments and content which may be easily analogized from the first to eighth embodiments will be omitted.

Configuration of Memory Cell Array

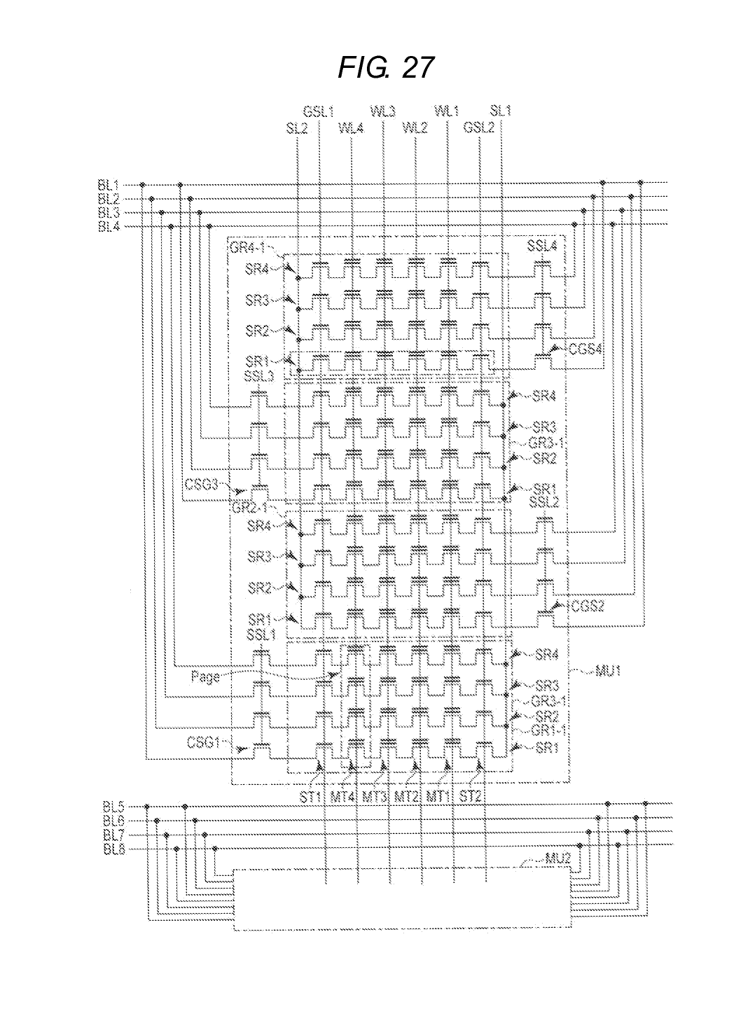

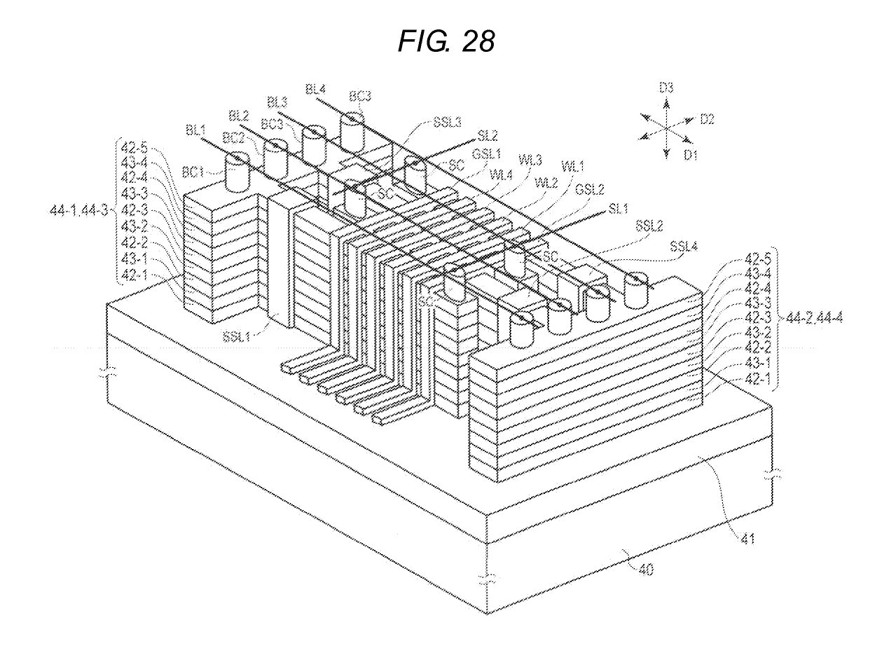

With reference to FIGS. 27 and 28, a description will be made of any one of blocks BLK of a memory cell array 230 according to the present embodiment. As illustrated in FIGS. 27 and 28, the block BLK includes a plurality of memory units MU (MU1 and MU2). Only the two memory units MU are illustrated in FIGS. 27 and 28, but the number thereof may be three or more, and is not limited thereto.

Each of the memory units MU includes, for example, four string groups GR (GR1 to GR4). In addition, when the memory units MU1 and MU2 are distinguished from each other, the string groups GR of the memory unit MU1 are respectively referred to as GR1-1 to GR4-1, and the string groups GR of the memory unit MU2 are respectively referred to as GR1-2 to GR4-2.

Each of the string groups GR includes, for example, four NAND strings SR (SR1 to SR4). Of course, the number of NAND strings SR is not limited to four, and may be five or more, and may be three or less. Each of the NAND strings SR includes selection transistors ST1 and ST2, and four memory cell transistors MT (MT1 to MT4). The number of memory cell transistors MT is not limited to four, and may be five or more, and may be three or less.

In the string group GR, the four NAND strings SR1 to SR4 are sequentially stacked on a semiconductor substrate, the NAND string SR1 is formed in the lowermost layer, and the NAND string SR4 is formed in the uppermost layer. In other words, in the first embodiment, the memory cell transistors MT in the NAND string are vertically stacked on the semiconductor substrate, whereas, in the present embodiment, the memory cell transistors MT in the NAND string are disposed in parallel to the semiconductor substrate surface, and the NAND strings are vertically stacked thereon. In addition, the selection transistors ST1 and ST2 included in the same string group GR are respectively connected to the same selection gate lines GSL1 and GSL2, and control gates of the memory cell transistors MT located in the same column are connected to the same word line WL. Further, drains of the four selection transistors ST1 in a certain string group GR are connected to different bit lines BL, and sources of the selection transistors ST2 are connected to the same source line SL.

The odd-numbered string groups GR1 and GR3 and the even-numbered string groups GR2 and GR4 are disposed so that the selection transistors ST1 and ST2 are opposite to each other in a positional relationship therebetween. As illustrated in FIG. 27, the selection transistors ST1 of the string groups GR1 and GR3 are disposed at the left ends of the NAND strings SR, and the selection transistors ST2 thereof are disposed at the right ends of the NAND strings SR. In contrast, the selection transistors ST1 of the string groups GR2 and GR4 are disposed at the right ends of the NAND strings SR, and the selection transistors ST2 thereof are disposed at the left ends of the NAND strings SR.

In addition, the gates of the selection transistors ST1 of the string groups GR1 and GR3 are connected to the same selection gate line GSL1, and the gates of the selection transistors ST2 thereof are connected to the same selection gate line GSL2. On the other hand, the gates of the selection transistors ST1 of the string groups GR2 and GR4 are connected to the same selection gate line GSL2, and the gates of the selection transistors ST2 thereof are connected to the same selection gate line GSL1.

In addition, the four string groups GR1 to GR4 included in a certain memory unit MU are mutually connected to the same bit lines BL, and different memory units MU are connected to different bit lines BL. More specifically, in the memory unit MU1, the drains of the selection transistors ST1 of the NAND strings SR1 to SR4 of each of the string groups GR1 to GR4 are respectively connected to the bit lines BL1 to BL4 via column selection gates CSG (CSG1 to CSG4). The column selection gates CSG have the same configuration as, for example, configurations of the memory cell transistors MT or the selection transistors ST1 and ST2, and selection a single string group GR which will be connected to the bit lines BL in each memory unit MU. Therefore, gates of the column selection gates CSG1 to CSG4 correlated with each string group GR are controlled by different control signal lines SSL1 to SSL4.

A plurality of memory units MU each having the above-described configuration are disposed in the vertical direction in FIG. 27. The plurality of memory units MU share the word lines WL and the selection gate lines GSL1 and GSL2 with the memory unit MU1. On the other hand, the bit lines BL are separately provided, and, for example, the memory unit MU2 is correlated with four bit lines BL5 to BL8 different from those of the memory unit MU1. The number of bit lines BL correlated with each memory unit MU corresponds to a total number of NAND strings SR included in a single string group GR. Therefore, if there are five layers of NAND strings, five bit lines BL are provided, and this is also the same for other numbers. In addition, the control signals SSL1 to SSL4 may be common to the memory units MU, or may be independently controlled.

In the above-described configuration, a set of plural memory cell transistors MT connected to the same word line WL in a single string group GR selected from each memory unit MU forms a “page”.

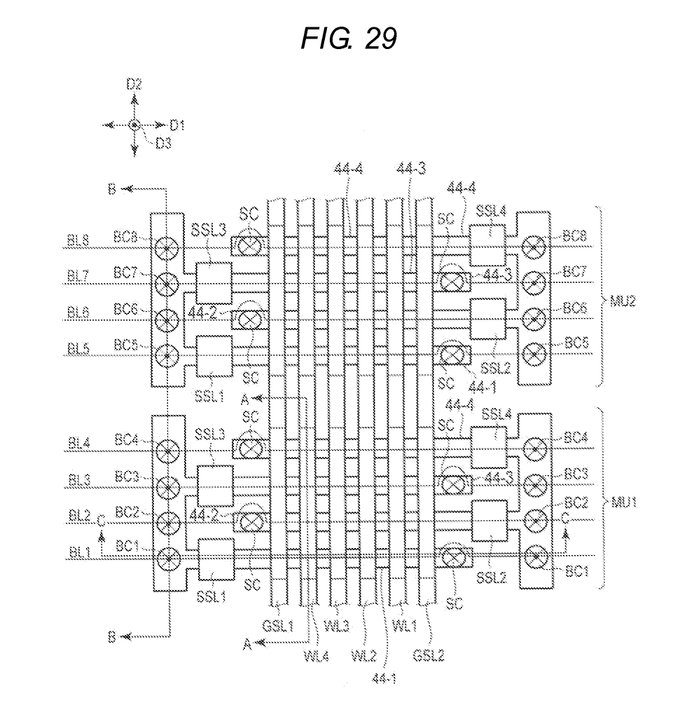

As illustrated in FIG. 29, an insulating film 41 is provided on the semiconductor substrate 40, and the block BLK is provided on the insulating film 41.

For example, four fin type structures 44 (44-1 to 44-4) having a stripe shape in a second direction perpendicular to a first direction which is a vertical direction to the surface of the semiconductor substrate 40 are provided on the insulating film. 41, and thus a single memory unit MU is formed. Each of the fin type structures 44 includes insulating films 42 (42-1 to 42-5) and semiconductor layers 43 (43-1 to 43-4) provided in the second direction. Further, in each of the fin type structures 44, the insulating films 42-1 to 42-5 and semiconductor layers 43-1 to 43-4 are alternately stacked, so that four stacked structures extending in the vertical direction to the surface of the semiconductor substrate 40 are formed. Each of the fin type structures 44 corresponds to the string group GR described in FIG. 27. The lowermost semiconductor layer 43-1 corresponds to a current path (a region where a channel is formed) of the NAND string SR1; the uppermost semiconductor layer 43-4 corresponds to a current path of the NAND string SR4; the semiconductor layer 43-2 interposed therebetween corresponds to a current path of the NAND string SR2; and the semiconductor layer 43-3 corresponds to a current path of the NAND string SR3.

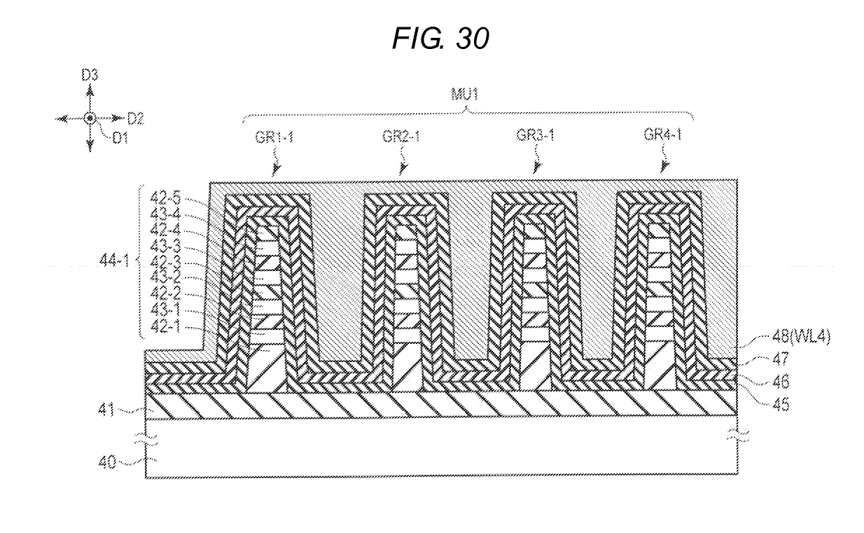

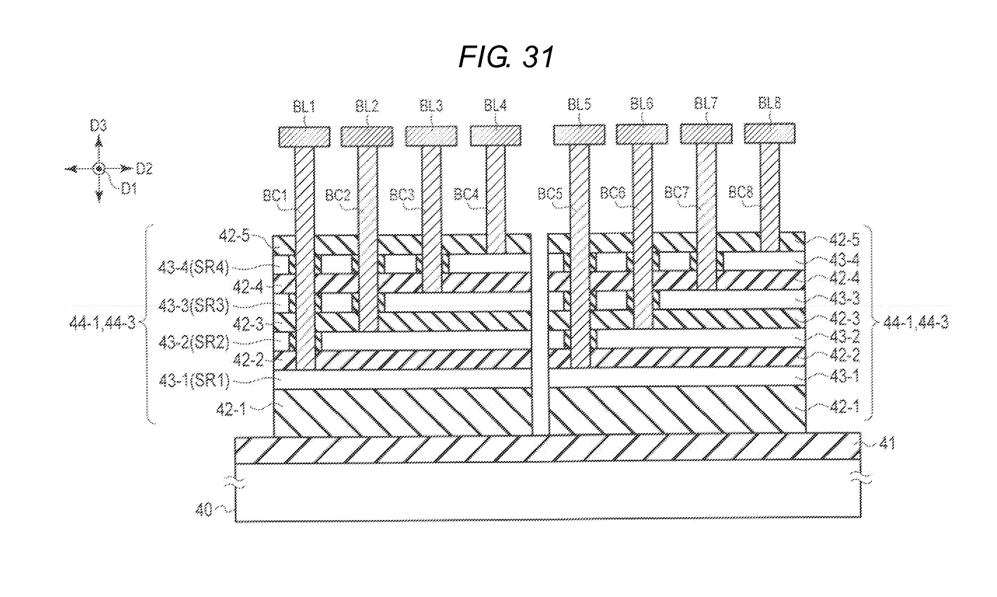

As illustrated in FIGS. 30 and 31, a gate insulating film 45, a charge storage layer 46, a block insulating film 47, and a control gate 48 are sequentially provided on upper surfaces and side surfaces of the fin type structures 44. The charge storage layer 46 is formed of, for example, an insulating film. In addition, the control gate 48 is formed of a conductive film, and functions as the word line WL or the selection gate lines GSL1 and GSL2. The word line WL and the selection gate lines GSL1 and GSL2 are formed to lie over the plurality of fin type structures 44 among the plurality of memory units MU. On the other hand, control signal lines SSL1 to SSL4 are independently provided for each of the fin type structures 44.

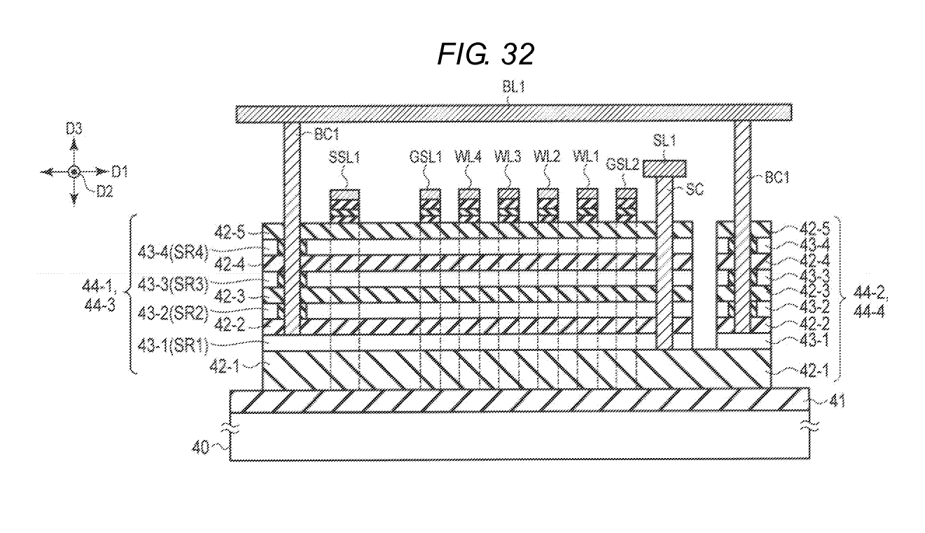

As illustrated in FIG. 32, first ends of the fin type structures 44 are extracted to the end of the block BLK, and are connected to the bit lines BL in an extracted region. In other words, as an example, looking at the memory unit MU1, the first ends of the odd-numbered fin type structures 44-1 and 44-3 are extracted to a certain region in the second direction and are connected in common, and contact plugs BC1 to BC4 are formed in this region. The contact plug BC1 formed in this region connects the semiconductor layer 43-1 of the string groups GR1 and GR3 to the bit line BL1, and is insulated from the semiconductor layers 43-2, 43-3 and 43-4. The contact plug BC2 formed in this region connects the semiconductor layer 43-2 of the string groups GR1 and GR3 to the bit line BL2, and is insulated from the semiconductor layers 43-1, 43-3 and 43-4. The contact plug BC3 formed in this region connects the semiconductor layer 43-3 of the string groups GR1 and GR3 to the bit line BL3, and is insulated from the semiconductor layers 43-1, 43-2 and 43-4. The contact plug BC4 formed in this region connects the semiconductor layer 43-4 of the string groups GR1 and GR3 to the bit line BL4, and is insulated from the semiconductor layers 43-1, 43-2 and 43-3.

On the other hand, first ends of the even-numbered fin type structures 44-2 and 44-4 are extracted to a region opposite to the first ends of the fin type structures 44-1 and 44-3 in the second direction and are connected in common, and contact plugs BC1 to BC4 are formed in this region. The contact plug BC1 formed in this region connects the semiconductor layer 43-1 of the string groups GR2 and GR4 to the bit line BL1, and is insulated from the semiconductor layers 43-2, 43-3 and 43-4. The contact plug BC2 formed in this region connects the semiconductor layer 43-2 of the string groups GR2 and GR4 to the bit line BL2, and is insulated from the semiconductor layers 43-1, 43-3 and 43-4. The contact plug BC3 formed in this region connects the semiconductor layer 43-3 of the string groups GR2 and GR4 to the bit line BL3, and is insulated from the semiconductor layers 43-1, 43-2 and 43-4. The contact plug BC4 formed in this region connects the semiconductor layer 43-4 of the string groups GR2 and GR4 to the bit line BL4, and is insulated from the semiconductor layers 43-1, 43-2 and 43-3.

Of course, the above description relates to the memory unit MU1. For example, in the memory unit MU2, as illustrated in FIG. 32, contact plugs BC5 to BC8 are formed, and respectively connect the semiconductor layers 43-1 to 43-4 to bit lines BL5 to BL8.

In addition, contact plugs SC are formed on second ends of the fin type structures 44. The contact plugs SC connect the semiconductor layers 43-1 to 43-4 to the source line SL.

In the above-described configuration, the memory cell transistors included in the NAND strings SR1 to SR4 have sizes different from each other. More specifically, as illustrated in FIG. 30, in each of the fin type structures 44, a width of the semiconductor layer 43 along the third direction becomes larger toward the lower layer, and becomes smaller toward the higher layer. In other words, the semiconductor layer 43-1 has the largest width, and the semiconductor layer 43-4 has the smallest width. In other words, a plurality of memory cell transistors MT having characteristics different from each other due to manufacturing variations are included in a single page.

As mentioned above, in the memory cell array 230 according to the present embodiment, capacitances of the semiconductor layers 43-1 to 43-4 may be different from each other due to the width variations of the semiconductor layers 43-1 to 43-4.

In the above-described respective embodiments, the semiconductor pillars SP are classified into the first group and the second group based on the magnitude of a capacitance. In addition, a sensing operation is performed in consideration of the capacitance of the first group bit line BLGP1 and the capacitance of the second group bit line BLGP2.

For example, in the present embodiment, the semiconductor layers 43-1 and 43-2 may be included in the first group GP1, and the semiconductor layers 43-3 and 43-4 may be included in the second group GP2. In this case, the bit lines BL1 and BL2 are included in the first group bit line BLGP1, and the bit lines BL3 and BL4 are included in the second group bit line BLGP2. In addition, the semiconductor layer 43-1 may be included in the first group GP1; the semiconductor layer 43-2 may be included in the second group GP2; the semiconductor layer 43-3 may be included in the third group GP3; and the semiconductor layer 43-4 may be included in the fourth group GP4. In this case, the bit line BL1 is included in the first group bit line BLGP1; the bit line BL2 is included in the second group bit line BLGP2; the bit line BL3 is included in the third group bit line BLGP3; and the bit line BL4 is included in the fourth group bit line BLGP4. A method of grouping the semiconductor layers 43-1 to 43-4 is not limited thereto.

The semiconductor layers 43-1 to 43-4 according to the present embodiment are grouped in the above-described manner, and the sense module and the operation thereof described in the respective embodiments may be applied thereto.

In addition, the above-described embodiments may be combined with each other. Specifically, the first and second embodiments may be combined with each other. Similarly, the first and second modification examples may be combined with each other. Further, the third to fifth embodiments may be combined with each other. Similarly, the third to fifth modification examples may be combined with each other. Still further, the sixth to eighth embodiments may be combined with each other. Similarly, the sixth to eighth modification examples may be combined with each other.

In the respective embodiments, an operation of the sense module during a data reading operation is described, but the exemplary embodiments are not limited thereto, and may be applied to, for example, program verification.

In the respective embodiments, (1) during a reading operation, a voltage applied to a word line which is selected for an A-level reading operation is in a range of, for example, 0 V to 0.55 V. A voltage is not limited thereto, and may be in any one of ranges of 0.1 V to 0.24 V, 0.21 V to 0.31 V, 0.31 V to 0.4 V, 0.4 V to 0.5 V, and 0.5 V to 0.55 V.

A voltage applied to a word line which is selected for a B-level reading operation is in a range of, for example, 1.5 V to 2.3 V. A voltage is not limited thereto, and may be in any one of ranges of 1.65 V to 1.8 V, 1.8 V to 1.95 V, 1.95 V to 2.1 V, and 2.1 V to 2.3 V.

A voltage applied to a word line which is selected for a C-level reading operation is, for example, in a range of 3.0 V to 4.0 V. A voltage is not limited thereto, and may be in any one of ranges of 3.0 V to 3.2 V, 3.2 V to 3.4 V, 3.4 V to 3.5 V, 3.5 V to 3.6 V, and 3.6 V to 4.0 V.

The time (tR) for the reading operation may be in any one of ranges of, for example, 25 μs to 38 μs, 38 μs to 70 μs, and 70 μs to 80 μs.

(2) A writing operation includes a programming operation and a verification operation as described above. In the writing operation, a voltage which is initially applied to a word line selected during the programming operation is in a range of, for example, 13.7 V to 14.3 V. A voltage is not limited thereto, and may be in either one of ranges of, for example, 13.7 V to 14.0 V, and 14.0 V to 14.6 V.

A voltage which is initially applied to a selected word line when data is written to an odd-numbered word line, and a voltage which is initially applied to a selected word line when data is written to an even-numbered word line, may be changed.

When the programming operation is performed by using an incremental step pulse program (ISPP) method, for example, about 0.5 V may be used as a step-up voltage.

A voltage applied to an unselected word line may be in a range of, for example, 6.0 V to 7.3V. A voltage is not limited thereto, and may be in a range of, for example, 7.3 V to 8.4 V, and may be equal to or lower than 6.0 V.

An applied path voltage may be changed depending on whether an unselected word line is an odd-numbered word line or an even-numbered word line.

The time (tProg) for the writing operation may be in ranges of, for example, 1,700 μs to 1,800 μs, 1,800 μs to 1,900 μs, and 1,900 μs to 2,000 μs.

(3) In an erasing operation, a voltage which is initially applied to the well which is formed in the upper part of the semiconductor substrate and on which the memory cell is disposed, is in a range of, for example, 12 V to 13.6 V. A voltage is not limited thereto, and may be in ranges of 13.6 V to 14.8 V, 14.8 V to 19.0 V, 19.0 V to 19.8 V, and 19.8 V to 21 V.

The time (tErase) for the erasing operation may be in ranges of 3,000 μs to 4,000 μs, 4,000 μs to 5,000 μs, and 4,000 μs to 9,000 μs.

(4) The memory cell structure includes the charge storage layer which is disposed on the semiconductor substrate (a silicon substrate) via a tunnel insulating film with a film thickness of 4 nm to 10 nm. The charge storage layer may have a laminate structure of an insulating film such as SiN or SiON with a film thickness of 2 mm to 3 mm and polysilicon with a film thickness of 3 mm to 8 mm. A metal such as Ru may be added to polysilicon. An insulating film is provided on the charge storage layer. This insulating film has, for example, a silicon oxide film with a film thickness of 4 nm to 10 nm, interposed between a lower-layer high-k film with a film thickness of 3 nm to 10 nm and an upper-layer high-k film with a film thickness of 3 nm to 10 nm. The high-k film may be HfO, or the like. In addition, a film thickness of the silicon oxide film may be larger than a film thickness of the high-k film. A control electrode with a film thickness of 30 nm to 70 nm is formed on the insulating film via a material with a film thickness of 3 nm to 10 nm, for adjusting a work function. Here, the material for adjusting a work function is a metal oxide film such as TaO, or a metal nitride film such as TaN. Tungsten (W) or the like may be used for the control electrode.

In addition, an air gap may be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including a first memory cell and a second memory cell having a parasitic capacitance smaller than a parasitic capacitance of the first memory cell;
a first bit line that is electrically connected to the first memory cell;
a second bit line that is electrically connected to the second memory cell;
a first sense module that is electrically connected to the first bit line through a first transistor; and
a second sense module that is electrically connected to the second bit line through a second transistor, wherein
during sensing data stored in the first memory cell, the first transistor is turned on for a first period of time to electrically connect the first sense module to the first bit line, and
during sensing data stored in the second memory cell, the second transistor is turned on for a second period of time that is shorter than the first period of time, to electrically connect the second sense module to the second bit line.

2. The device according to claim 1, wherein the memory cell array includes:
a first memory string including a plurality of serially connected memory cells including the first memory cell, that are disposed above a semiconductor substrate, and a second memory string including a plurality of serially connected memory cells including the second memory cell, that are disposed above the semiconductor substrate, and
the first memory string has a first end electrically connected to the first bit line and a second end electrically connected to a source line, and the second memory string has a first end electrically connected to the second bit line and a second electrically connected to the source line.

3. The device according to claim 2, further comprising:
first and second semiconductor pillars extending above the substrate in parallel with each other;
first and second plate-shaped contacts extending above the substrate in parallel with each other and parallel to the first and second semiconductor pillars,
wherein the memory cells of the first memory string have portions along the first semiconductor pillar and the memory cells of the second memory string have portions along the second semiconductor pillar.

4. The device according to claim 3, wherein the first semiconductor pillar is closer to the first plate-shaped contact than the second semiconductor pillar is to either the first plate-shaped contact or the second plate-shaped contact.

5. The device according to claim 4, further comprising:
a third memory string including a plurality of serially connected memory cells that are disposed above the semiconductor substrate;
a third semiconductor pillar extending above the substrate in parallel to the first and second semiconductor pillars, wherein the memory cells of third first memory string have portions along the third semiconductor pillar; and
a third bit line that is electrically connected to the third memory string, wherein
the first, second, and third bit lines extend parallel to each other in a first direction, and
the second bit line is between the first and third bit lines, and the third semiconductor pillar is closer to the first plate-shaped contact than the second semiconductor pillar.

6. The device according to claim 5, further comprising:
a first bit line contact electrically connecting the first bit line to the first semiconductor pillar;
a second bit line contact electrically connecting the second bit line to the second semiconductor pillar; and
a third bit line contact electrically connecting the third bit line to the third semiconductor pillar, wherein
the first and second semiconductors are aligned in the first direction, and
the first and second bit line contacts are not aligned in the first direction.

7. The device according to claim 1, wherein the memory cell array includes:
a first memory string including a plurality of serially connected memory cells including the first memory cell, that are disposed in a first layer above the semiconductor substrate, and a second memory string including a plurality of serially connected memory cells including the second memory cell, that are disposed in a second layer higher above the semiconductor substrate than the first layer, and
the first memory string has a first end electrically connected to the first bit line and a second end electrically connected to a source line, and the second memory string has a first end electrically connected to the second bit line and a second electrically connected to the source line.

8. A semiconductor memory device comprising:
a memory cell array including a first memory cell and a second memory cell having a parasitic capacitance smaller than a parasitic capacitance of the first memory cell;
a first bit line that is electrically connected to the first memory cell;
a second bit line that is electrically connected to the second memory cell;
a first sense module that is electrically connected to the first bit line through first and second transistors that control precharging of the first bit line; and
a second sense module that is electrically connected to the second bit line through third and fourth transistors that control precharging of the second bit line, wherein
during precharging of the first bit line, the first and second transistors are turned on substantially at the same time, and
during precharging of the second bit line, the third transistor is turned on and the fourth transistor is turned on a period of time thereafter.

9. The device according to claim 8, wherein the memory cell array includes:
a first memory string including a plurality of serially connected memory cells including the first memory cell, that are disposed above a semiconductor substrate, and a second memory string including a plurality of serially connected memory cells including the second memory cell, that are disposed above the semiconductor substrate, and
the first memory string has a first end electrically connected to the first bit line and a second end electrically connected to a source line, and the second memory string has a first end electrically connected to the second bit line and a second electrically connected to the source line.

10. The device according to claim 9, further comprising:
first and second semiconductor pillars extending above the substrate in parallel with each other;
first and second plate-shaped contacts extending above the substrate in parallel with each other and parallel to the first and second semiconductor pillars,
wherein the memory cells of the first memory string have portions along the first semiconductor pillar and the memory cells of the second memory string have portions along the second semiconductor pillar.

11. The device according to claim 10, wherein the first semiconductor pillar is closer to the first plate-shaped contact than the second semiconductor pillar is to either the first plate-shaped contact or the second plate-shaped contact.

12. The device according to claim 11, further comprising:
a third memory string including a plurality of serially connected memory cells that are disposed above the semiconductor substrate;
a third semiconductor pillar extending above the substrate in parallel to the first and second semiconductor pillars, wherein the memory cells of third first memory string have portions along the third semiconductor pillar; and
a third bit line that is electrically connected to the third memory string, wherein
the first, second, and third bit lines extend parallel to each other in a first direction, and
the second bit line is between the first and third bit lines, and the third semiconductor pillar is closer to the first plate-shaped contact than the second semiconductor pillar.

13. The device according to claim 12, further comprising:
a first bit line contact electrically connecting the first bit line to the first semiconductor pillar;
a second bit line contact electrically connecting the second bit line to the second semiconductor pillar; and
a third bit line contact electrically connecting the third bit line to the third semiconductor pillar, wherein
the first and second semiconductors are aligned in the first direction, and
the first and second bit line contacts are not aligned in the first direction.

14. The device according to claim 8, wherein the memory cell array includes:
a first memory string including a plurality of serially connected memory cells including the first memory cell, that are disposed in a first layer above the semiconductor substrate, and a second memory string including a plurality of serially connected memory cells including the second memory cell, that are disposed in a second layer higher above the semiconductor substrate than the first layer, and
the first memory string has a first end electrically connected to the first bit line and a second end electrically connected to a source line, and the second memory string has a first end electrically connected to the second bit line and a second electrically connected to the source line.

15. A semiconductor memory device comprising:
a memory cell array including a first memory cell and a second memory cell having a parasitic capacitance smaller than a parasitic capacitance of the first memory cell;
a first bit line that is electrically connected to the first memory cell;
a second bit line that is electrically connected to the second memory cell;
a first sense module that is electrically connected to the first bit line through a first transistor that controls precharging of the first bit line; and
a second sense module that is electrically connected to the second bit line through a second transistor that controls precharging of the second bit line, wherein
during precharging of the first bit line, a first control voltage is applied to a gate of the first transistor to turn on the first transistor, and
during precharging of the second bit line, a second control voltage, lower than the first control voltage, is applied to a gate of the second transistor to turn on the second transistor.

16. The device according to claim 15, wherein the memory cell array includes:
a first memory string including a plurality of serially connected memory cells including the first memory cell, that are disposed above a semiconductor substrate, and a second memory string including a plurality of serially connected memory cells including the second memory cell, that are disposed above the semiconductor substrate, and
the first memory string has a first end electrically connected to the first bit line and a second end electrically connected to a source line, and the second memory string has a first end electrically connected to the second bit line and a second electrically connected to the source line.

17. The device according to claim 16, further comprising:
first and second semiconductor pillars extending above the substrate in parallel with each other;
first and second plate-shaped contacts extending above the substrate in parallel with each other and parallel to the first and second semiconductor pillars,
wherein the memory cells of the first memory string have portions along the first semiconductor pillar and the memory cells of the second memory string have portions along the second semiconductor pillar.

18. The device according to claim 17, wherein the first semiconductor pillar is closer to the first plate-shaped contact than the second semiconductor pillar is to either the first plate-shaped contact or the second plate-shaped contact.

19. The device according to claim 18, further comprising:
a third memory string including a plurality of serially connected memory cells that are disposed above the semiconductor substrate;
a third semiconductor pillar extending above the substrate in parallel to the first and second semiconductor pillars, wherein the memory cells of third first memory string have portions along the third semiconductor pillar; and
a third bit line that is electrically connected to the third memory string, wherein
the first, second, and third bit lines extend parallel to each other in a first direction, and
the second bit line is between the first and third bit lines, and the third semiconductor pillar is closer to the first plate-shaped contact than the second semiconductor pillar.

20. The device according to claim 19, further comprising:
a first bit line contact electrically connecting the first bit line to the first semiconductor pillar;
a second bit line contact electrically connecting the second bit line to the second semiconductor pillar; and
a third bit line contact electrically connecting the third bit line to the third semiconductor pillar, wherein the first and second semiconductors are aligned in the first direction, and
the first and second bit line contacts are not aligned in the first direction.
